(19) United States
(12) Patent Application Publication
(10) Pub. No.: US 2013/0238264 A1
(43) Pub. Date: Sep. 12, 2013

(54) MEASUREMENT DEVICE FOR IDENTIFYING ELECTROMAGNETIC INTERFERENCE SOURCE, METHOD FOR ESTIMATING THE SAME, AND COMPUTER READABLE INFORMATION RECORDING MEDIUM ENABLING OPERATIONS THEREOF

(71) Applicants: Satoshi KAZAMA, Tokyo (JP); Hiroshi TUTAGAYA, Tokyo (JP)

(72) Inventors: Satoshi KAZAMA, Tokyo (JP); Hiroshi TUTAGAYA, Tokyo (JP)

(73) Assignee: TAIYO YUDEN CO., LTD., Tokyo (JP)

(21) Appl. No.: 13/601,990

(22) Filed: Aug. 31, 2012

(30) Foreign Application Priority Data
Sep. 1, 2011 (JP) 2011-190268

(51) Int. Cl. G01R 31/08

(52) U.S. Cl. CPC G01R 31/088
USPC 702/59

(57) ABSTRACT

With regard to EMC problems resulting from interference electromagnetic wave emitted from a subject electronic device, a source of interference electromagnetic wave is accurately located by measuring near-field electromagnetic wave emitted from the subject electronic device. The waveform of an electromagnetic wave received by an antenna under interference is compared with the waveform of an electromagnetic wave detected by a sensor, which moves across a vicinity of the subject electronic device, and when the temporal changes in amplitudes of these waveforms coincide with each other, or when a phase difference between the signals is found fairly constant over time, the position of the sensor at which such condition is found and/or the vicinity thereof is identified as the location of a source of the interference electromagnetic wave.

This application claims the benefit of Japanese Application No. 2011-190268 filed in Japan on Sep. 1, 2011, which is hereby incorporated by reference in its entirety.

### BACKGROUND OF THE INVENTION

1. Field of the Invention

The present invention relates to a measurement device that identifies a source of interference electromagnetic waves with regard to an EMC problem caused by interference electromagnetic waves emitted from an electronic device, a method of identifying the same, and to an information recording medium having computer programs for performing operations thereof. In one mode of the invention, near-field electromagnetic field of the source is effectively and efficiently measured and analyzed.

2. Description of Related Art

In recent years, sophisticated portable terminals are equipped with a semiconductor in which multiple functions such as a DC-DC converter with a plurality of channels, a power saving function, and a protective circuit are integrated in a single chip, thereby achieving higher switching frequencies and lower voltage driving. Because electromagnetic waves emitted from portable electronic devices equipped with a wireless communication function have been becoming a problem in particular, the industry groups around the world have set a standard for the intensity of electromagnetic wave emission. Against this background, electronic device manufacturers are adopting various technologies to deal with the EMC issue in developing and designing devices so as to reduce unwanted electromagnetic wave emission. In order to deal with the EMC issue, it is necessary to measure the intensity of electromagnetic fields at a position that is about several meters away from an object to be measured in an open site or in an anechoic chamber so as to confirm that the target electronic device meets the standard.

Further, a problem of intra-system EMC or EMI (Electromagnetic Interference), which is the interference of the electromagnetic waves emitted from the electronic device with a function of the electronic device itself or with a function of another device, has also arisen.

In order to minimize such problems, a technology of measuring a distribution of electromagnetic field in the vicinity of an electronic device to identify the potential cause and mechanism of the interference and to implement countermeasures has been proposed. See Patent Documents 1 to 4, for example.

Conventional methods of measuring the electromagnetic field distribution include a method of performing a scan with an electromagnetic field sensor, measuring the output thereof by a spectrum analyzer, and displaying the intensity distribution of the electromagnetic field. The spectrum analyzer conducts an evaluation on the intensity at a given time, taking no consideration of a temporal change. That is, in this method, a point with the strongest intensity in the displayed electromagnetic field distribution is identified as the potential interference source, with taking into no account the temporal change.

### RELATED ART DOCUMENTS

### Patent Documents

Patent Document 1: Japanese Patent Application Laid-Open Publication No. 2002-372558
Patent Document 2: Japanese Patent Application Laid-Open Publication No. 2006-201007
Patent Document 3: Japanese Patent Application Laid-Open Publication No. 2006-337082
Patent Document 4: Japanese Patent Application Laid-Open Publication No. 2011-17718

### SUMMARY OF THE INVENTION

However, with the electromagnetic field distribution that shows the intensity only and that does not take into account the temporal change thereof, when signals having the same frequency are present at a plurality of locations, the potential interference source cannot be identified effectively. When an IC has a plurality of output terminals, for example, if it is possible to determine which output terminal outputs the signal that becomes the interference source, an effective countermeasure can be implemented for that particular interference source. However, if signals outputted from a plurality of output terminals of the IC are synchronized with the same operating clock signal, electromagnetic fields of the same frequency are generated, and therefore, the interference source cannot be identified just by measuring the intensity of the electromagnetic field emitted from each output terminal of the IC.

As described above, when the measurement was conducted only for the distribution of the intensity of the emitted electromagnetic fields, signals that are irrelevant to an interference source in the intra-system EMC or to fundamental noise that results in unwanted emission EMI were also detected, which made it difficult to pinpoint the position of the interference source. For this reason, additional countermeasures were needed to deal with the candidate sources that were not actually causing the problem.

The present invention was made in view of the above-mentioned problems, and aims to provide a measurement device capable of identifying a source of interference electromagnetic wave with regard to an EMC problem caused by interference electromagnetic waves emitted from an electronic device, a method of identifying the same, and an information recording medium having computer programs for performing operations thereof. In one mode of the invention, near-field electromagnetic field of the source is effectively and efficiently measured and analyzed.

Additional or separate features and advantages of the invention will be set forth in the descriptions that follow and in part will be apparent from the description, or may be learned by practice of the invention. The objectives and other advantages of the invention will be realized and attained by the structure particularly pointed out in the written description and claims thereof as well as the appended drawings.

To achieve these and other advantages and in accordance with the purpose of the present invention, as embodied and broadly described, in one aspect, the present invention provides a method of identifying an electromagnetic interference source, in which a position of a source of interference electromagnetic wave that is emitted from an electronic device is identified by using an electromagnetic interference source identification device that includes: a sensor disposed to be movable in a vicinity of the electronic device that emits the interference electromagnetic wave, the sensor being provided to receive near-field electromagnetic field and to output signal power of the received near-field electromagnetic field as first signal power; a first signal detection section that receives the first signal power outputted from the sensor, the first signal detection section outputting a first digital value that corresponds to an amplitude of the first signal power; a second signal detection section that receives signal power of interference electromagnetic wave received by an electronic device under interference as second signal power, the second signal detection section outputting a second digital value that corresponds to an amplitude of the second signal power; and a computer device that receives the first and second digital values, wherein the computer device perform the method that includes: obtaining the first digital value outputted from the first signal detection section at each prescribed sampling time, and storing the first digital values in a first memory at an appropriately assigned memory address; obtaining the second digital value outputted from the second signal detection section at each prescribed sampling time, and storing the second digital values in a second memory at an appropriately assigned memory address; and comparing a change over time in the first digital value stored in the first memory with a change over time in the second digital value stored in the second memory to derive a degree of coincidence or a degree of discrepancy between these two changes, and displaying the degree of coincidence or the degree of discrepancy.

In another aspect, the present invention proposes a method of identifying an electromagnetic interference source, in which a position of a source of interference electromagnetic wave that is emitted from an electronic device is identified by using an electromagnetic interference source identification device that includes: a sensor disposed to be movable in a vicinity of the electronic device that emits the interference electromagnetic wave, the sensor being provided to receive near-field electromagnetic field and to output signal power of the received near-field electromagnetic field as first signal power; a first signal detection section that receives the first signal power outputted from the sensor, the first signal detection section outputting a first phase digital value that corresponds to a phase of the first signal power on the basis of a prescribed reference signal; a second signal detection section that receives signal power of interference electromagnetic wave received by an electronic device under interference as second signal power, the second signal detection section outputting a second phase digital value that corresponds to a phase of the second signal on the basis of a prescribed reference signal; and a computer device that receives the first phase digital value and the second phase digital value, wherein the computer device performs the method that includes: obtaining the first phase digital value outputted from the first signal detection section at each prescribed sampling time, and storing the first phase digital value in a first memory at an appropriately assigned memory address; obtaining the second phase digital value outputted from the second signal detection section at each prescribed sampling time, and storing the second phase digital value in a second memory at an appropriately assigned memory address; and deriving a degree of coincidence or a degree of discrepancy from a temporal consistency in differences between the first phase digital values stored in the first memory and the second phase digital values stored in the second memory, i.e., a phase difference over the course of time, and displaying the degree of coincidence or the degree of discrepancy.

In another aspect, the present invention also provides a computer readable information recording medium in which computer programs for operating a device that performs the above-mentioned method and/or the above-mentioned computer device are recorded.

According to the present invention, it becomes possible to identify a source that emits interference electromagnetic waves having temporal characteristics that are similar to the temporal signal characteristics of the interference power received at an antenna under influence of interference. This enables more accurate and efficient determination of the location and/or identification of the interference source(s), and allows more localized and efficient countermeasures for the EMC problems to implement.

It is to be understood that both the foregoing general description and the following detailed description are exemplary and explanatory, and are intended to provide further explanation of the invention as claimed.

### BRIEF DESCRIPTION OF THE DRAWINGS

FIG. 1 is a block diagram showing an electric circuit of an electromagnetic interference source identification device according to Embodiment 1 of the present invention.

FIG. 2 is a diagram showing a relationship between time and signal power amplitude stored in a first memory.

FIG. 3 is a diagram showing a relationship between time and signal power amplitude stored in a second memory.

FIG. 4 is a flowchart that shows an operation of the electromagnetic interference source identification device according to Embodiment 1 of the present invention.

FIG. 5 is a diagram showing a voltage waveform of a signal that travels through a digital signal line such as an address bus line or a data bus line according to one example.

FIG. 6 is a diagram showing details of a voltage waveform of the signal that travels through a digital signal line such as an address bus line or a data bus line according to one example.

FIG. 7 is a block diagram of an electric circuit showing another configuration example of Embodiment 1 of the present invention.

FIG. 8 is a block diagram of an electric circuit showing another configuration example of Embodiment 1 of the present invention.

FIG. 9 is a flowchart showing an operation of an electromagnetic interference source identification device according to Embodiment 2 of the present invention.

FIG. 10 is a plan view of an electronic device according to Embodiment 2 of the present invention.

FIG. 11 is a mapping chart showing the degree of discrepancy in Embodiment 2 of the present invention.

FIG. 12 is a diagram showing a signal waveform of an electromagnetic wave that was received by an antenna in Embodiment 2 of the present invention.

FIG. 13 is a diagram showing a signal waveform of an electromagnetic wave that was detected in a range of a level D3 by a sensor in Embodiment 2 of the present invention.

FIG. 14 is a diagram showing a signal waveform of an electromagnetic wave that was detected in a range of a level D4 by the sensor in Embodiment 2 of the present invention.

FIG. 15 is a diagram showing a signal waveform of an electromagnetic wave that was detected in a range of a level D6 by the sensor in Embodiment 2 of the present invention.

FIG. 16 is a block diagram showing an electric circuit of an electromagnetic interference source identification device according to Embodiment 3 of the present invention.

FIG. 17 is a diagram showing an example of a phase difference measured in Embodiment 3 of the present invention.

FIG. 18 is a diagram showing an example of a phase difference measured in Embodiment 3 of the present invention.

FIG. 19 is a diagram showing an example of a phase difference measured in Embodiment 3 of the present invention.

FIG. 20 is a diagram showing an occurrence frequency distribution of a phase difference measured in Embodiment 3 of the present invention.

FIG. 21 is a diagram showing an occurrence frequency distribution of a phase difference measured in Embodiment 3 of the present invention.

FIG. 22 is a diagram showing an occurrence frequency distribution of a phase difference measured in Embodiment 3 of the present invention.

FIG. 23 is a flowchart showing an operation of the electromagnetic interference source identification device according to Embodiment 3 of the present invention.

FIG. 24 is a block diagram of an electric circuit showing another configuration example of Embodiment 3 of the present invention.

FIG. 25 is a block diagram of an electric circuit showing another configuration example of Embodiment 3 of the present invention.

FIG. 26 is a flowchart showing an operation of an electromagnetic interference source identification device according to Embodiment 4 of the present invention.

### DETAILED DESCRIPTION OF THE PREFERRED EMBODIMENTS

Embodiments of the present invention will be described below with reference to figures.

Embodiment 1 will be described first.

In Embodiment 1, a sensor for detecting electromagnetic waves is moved across a measurement area of an electronic device emitting the interference electromagnetic waves. An exemplary device of Embodiment 1 identifies a vicinity of a particular sensor position as a source of interference electromagnetic wave, when a temporal waveform of the amplitude of an electromagnetic wave detected by the sensor at that sensor position substantially coincides with a temporal waveform of the amplitude of an electromagnetic wave received by an antenna under interference. Here, the temporal changes in the amplitudes of the received electromagnetic waves are compared, and the degree of discrepancy at each of the respective positions of the sensor is calculated in order to identify the source location/source itself.

For example, with respect to the changes in the amplitudes of the signals of received electromagnetic waves over the course of time, when the signal received by the antenna under interference changes in the pattern of strong (a dB), weak (−b dB), strong (c dB), weak (−d dB) at certain intervals, if the signal detected by the electromagnetic wave sensor changes in the pattern of strong, weak, strong, weak, i.e., (a, −b, c, −d dB), which is the same as that of the signal received by the antenna, the two signals coincide with each other 100%, and the error rate is 0 dB/point. When the signal detected by the electromagnetic wave sensor changes in the pattern of (e, f, g, h dB), the error rate (degree of discrepancy) can be represented by (|(a−e)|+|(−b−f))|+|(c−g)|+|(−d−h)|)/4·[dB/point]. Because the degree of coincidence of two different thermal noises is very low, if the error rate of the two signals is about the same as the error rate of these thermal noises, the degree of coincidence between these signals can be deemed sufficiently low. As described above, it becomes possible to precisely locate the source of interference electromagnetic waves on the basis of the degree of coincidence of the amplitudes of the electromagnetic waves.

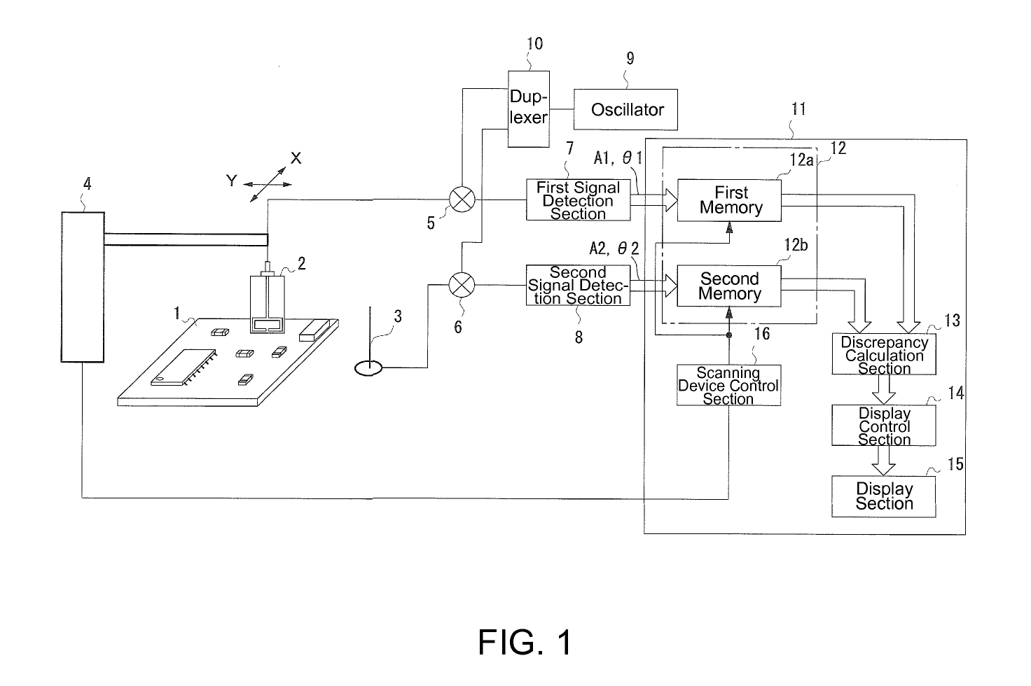

FIG. 1 is a block diagram showing an electric circuit of an electromagnetic interference source identification device according to Embodiment 1 of the present invention.

In the figure, the reference character 1 is an electronic device such as a circuit board for a mobile phone, for example, that is suspected to emit interfering electromagnetic waves. The device 1 itself may be influenced by interfering electromagnetic waves emitted from itself. The reference character 2 is a sensor for scanning, which is a probe antenna with a shielded loop structure, for example. The reference character 3 is an antenna for receiving interference waves, which is made of a mono-pole antenna, for example. The reference character 4 is a scanning device that activates the sensor 2 to move across a prescribed scanning plane provided around the electronic device 1 to scan the surface of the device 1. The reference characters 5 and 6 represent mixers. The reference characters 7 represents a first signal detection section, 8 represents a second signal detection section, 9 represents an oscillator, 10 represents a duplexer, 11 represents a computer device, 12 represents a processing section, 13 represents a discrepancy calculation section, 14 represent a display control section, 15 represent a display section, and 16 represents a scanning device control section.

The electromagnetic interference source identification device in the present embodiment is constituted of the constituting elements described above except for the electronic device 1.

The sensor 2 is connected to the first signal detection section 7 through the mixer 5. The antenna 3 is connected to the second signal detection section 8 through the mixer 6.

The mixers 5 and 6 respectively receive reference signals for frequency conversion that were generated by the oscillator 9 and that were divided by the duplexer 10. This way, the signals that are inputted into the first signal detection section 7 and the second signal detection section 8 are down-converted by the mixers 5 and 6, respectively.

Although not shown in the figure, filters are provided in the down-conversion such that only necessary signals for measurement are inputted into the first signal detection section 7 and the second signal detection section 8, thereby preventing unwanted signals and the like generated in the mixing from affecting the first signal detection section 7 and the second signal detection section 8.

The first signal detection section 7 has a quadrature demodulator and an analog-digital converter, and can obtain two pieces of digital data I and Q, which are 90° out of phase with each other based on an internal reference signal used in the quadrature demodulator. By conducting digital filtering to these data to extract the frequency components to be measured, the amplitude of the input signal power of the measurement frequency band, which was inputted to the first signal detection section 7, is outputted as a digital value A1 (first digital value), and the phase information thereof is outputted as a digital value θ1 (first phase digital value). The signal used in the quadrature demodulator is used as a reference for the phase θ1. The two digital values for the amplitude and the phase that were outputted from the first signal detection section 7 are inputted into the processing section 12 of the computer device 11.

In a manner similar to the first signal detection section 7, the second signal detection section 8 outputs the amplitude of the input signal power as a digital value A2 (second digital value), and outputs the phase information as a digital value θ2 (second phase digital value). The two digital values of the amplitude and the phase that were outputted from the second signal detection section 8 are inputted into the processing section 12 of the computer device 11.

The computer device 11 is operated by computer programs that are stored in a not-shown memory section in advance, and is equipped with the processing section 12 including a first memory 12a and a second memory 12b, the discrepancy calculation section 13, the display control section 14, the display section 15, and the scanning device control section 16. These constituting sections provided in the computer device 11 are constituted of computer programs and/or hardware.

At each of the positions assumed by the sensor 2, the following procedure is performed to obtain temporal characteristics of the electromagnetic waves received by the sensor 2 and the antenna 3, respectively, at that sensor location. Specifically, at prescribed sampling intervals “ts,” the processing section 12 receives coordinate information (positional information) of the sensor 2 on the XY plane, which is outputted from the scanning device control section 16, and stores the amplitude digital value A1 (first digital value) and the phase digital value θ1 (first phase digital value), which are outputted from the first signal detection section 7, as well as the coordinate information of the sensor 2 in the first memory 12a at appropriately assigned memory addresses. At the same timings (i.e., at the prescribed sampling intervals “ts”), the processing section 12 also stores the amplitude digital value A2 (second digital value) and the phase digital value θ2 (second phase digital value), which are outputted from the second signal detection section 8, as well as the associated coordinate information of the sensor 2 in the second memory 12b at appropriately assigned memory addresses.

Then, for each of the assumed positions of sensor 2, the discrepancy calculation section 13 reads out the amplitude values of the respective signal powers, which are stored in the first memory 12a and the second memory 12b, respectively. By using these read-out amplitude values, the degree of discrepancy between the amplitude of the signal power detected by the sensor 2 and the amplitude of the signal power received by the antenna 3 is calculated for each of the locations of the sensor 2.

In the example device shown in FIG. 1, for each of the sensor positions, the amplitude values A1=(A11, A12, . . . A1n) of the signal power detected by the sensor 2 and the phase values θ1=(θ11, θ12, . . . θ1n) thereof are stored in the first memory 12a, and the amplitude values A2=(A21, A22, . . . A2n) of the signal power received by the antenna 3 and the phase values θ2=(θ21, θ22, . . . θ2n) thereof are stored in the second memory 12b. In the present embodiment, the amplitude values A1, A2 are used, and the phase values θ1, θ2 are not used. Thus, the memories 12a and 12b can store only the respective amplitude values and can be configured not to store the phase values in this example.

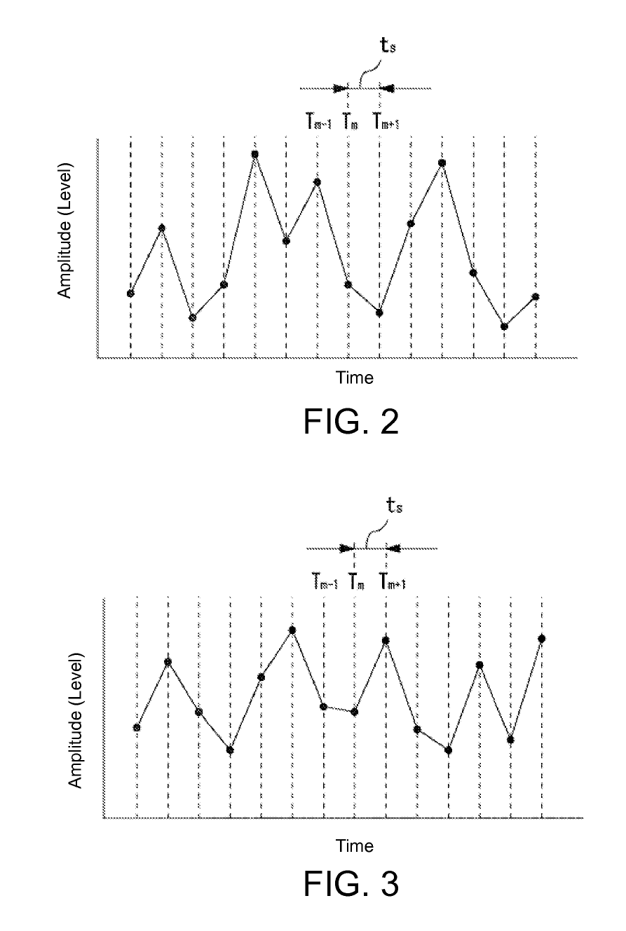

An example of the amplitude values determined from the signals received at the sensor 2 and the antenna 3, respectively, for a particular position of the sensor 2 is shown in FIGS. 2 and 3. The amplitude values of the signal power stored in the first memory 12a exhibits a temporal change a manner shown in FIG. 2 in this example. As shown in FIG. 2, the sampling from the first signal detection section 7 occurred at sampling times Tm at sampling intervals “ts” (=T(m+1)−Tm; m is a positive integer) in this example. The amplitude values of the signal power stored in the second memory 12b exhibit a temporal change in a manner shown in FIG. 3, for example, (at the same timings as in FIG. 2).

The measurement time can be represented by “sampling interval “ts”×sampling size “n” (“n” is a positive integer).” It is preferable that the sampling interval “ts” and the sampling size “n” be appropriately set in accordance with noise to be measured. In calculating the degree of discrepancy, the complete set of measurement data may be used, or selected data may be used.

The degree of discrepancy can be calculated by the following formula (1).

$$\begin{matrix}Formula 1 & \\ Degree of discrepancy = {\sum }_{m = 1}^{n} \vert ( A 1 ( m + 1 ) - A 1 m ) - ( A 2 ( m + 1 ) - A 2 m ) \vert & ( 1 )\end{matrix}$$

In this example, the degree of discrepancy is derived by calculating the absolute value of a difference between the amount of change in the amplitude of the signal power detected by the sensor 2 and the amount of change in the amplitude of the signal power received by the antenna 3 at each sampling interval, and by summing up the absolute values from the beginning of the measurement time to the end thereof.

The smaller the degree of discrepancy derived by the formula (1) above is, the higher the degree of coincidence between the change in the amplitude of the signal power detected by the sensor 2 and the change in the amplitude of the signal power received by the antenna 3 becomes. The position of the sensor 2 or its vicinity at which these two temporal waveforms have the highest degree of coincidence (in terms of temporal changes in amplitude in this example) can be identified as the source and/or location of the interference electromagnetic waves.

The degree of discrepancy may also be derived by calculating an average of the respective absolute values as shown in the following formula (2).

$$\begin{matrix}Formula 2 & \\ Degree of discrepancy = {\sum }_{m = 1}^{n} \vert ( A 1 ( m + 1 ) - A 1 m ) - ( A 2 ( m + 1 ) - A 2 m ) \vert / n & ( 2 )\end{matrix}$$

By using the average value as the degree of discrepancy, the value of the degree of discrepancy can remain small even if the sampling size “n” becomes large, unlike the case in which the accumulated value is used as the degree of discrepancy. It also makes it possible to compare the degree of discrepancy between different sampling sizes “n.”

The display control section 14 receives the degree of discrepancy derived by the discrepancy calculation section 13 and positional information of the sensor 2 that corresponds to the degree of discrepancy from the discrepancy calculation section 13, and displays the positional information of the sensor 2 and the degree of discrepancy in the display section 15.

The scanning device control section 16 controls a drive of the scanning device 4 such that the sensor 2 is moved across a prescribed measurement plane (XY plane), which is provided in a vicinity of the electronic device 1, and outputs the positional information (XY coordinates) of the sensor 2 to the first memory 12a and to the second memory 12b.

In displaying the measurement results, it is possible to display the degree of discrepancy at the then current position of the sensor 2 only. Alternatively, the results may be shown as a table that shows the degrees of discrepancy at all of the respective measured positions of the sensor 2 at once. It is preferable to appropriately set the display format.

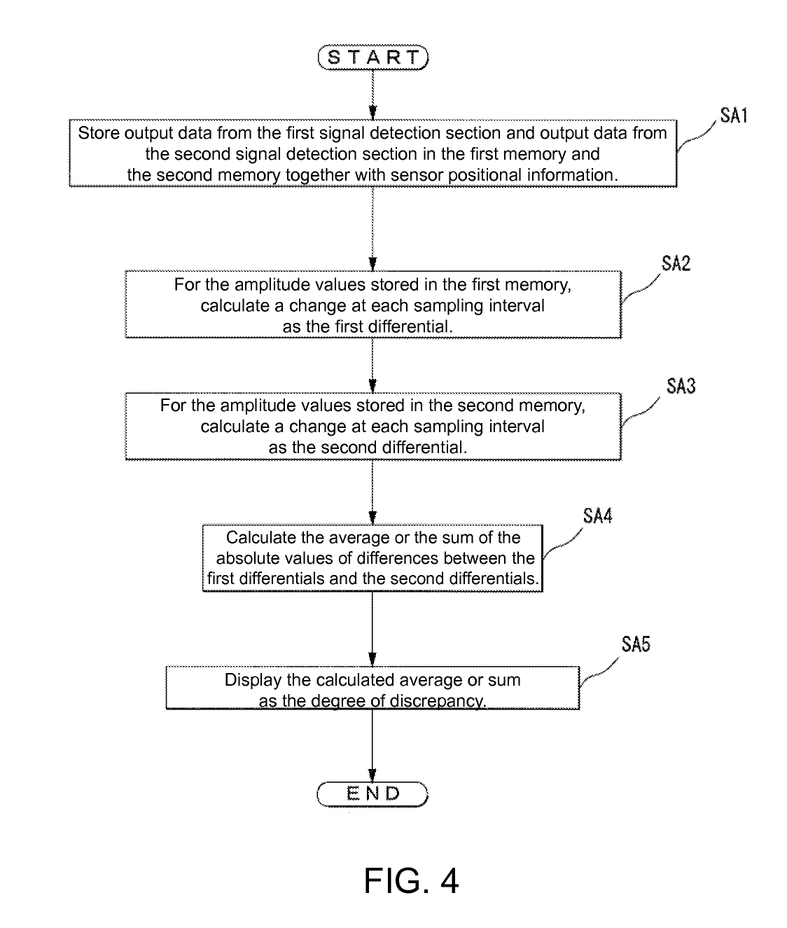

Next, an operation of the electromagnetic interference source identification device in the present embodiment will be explained with reference to a flowchart shown in FIG. 4.

When the measurement is started, the computer device 11 performs the following steps SA1 to SA5 (see FIG. 4) for a particular position of the sensor 2 (and successively for each of the positions of the sensor 2 when needed).

That is, the positional information of the sensor 2 and the output data (the amplitude values described above (and the phase values, if used as in other embodiments described below)) from the first signal detection section 7 are stored in the first memory 12a, and the positional information of the sensor 2 and the output data (the amplitude values described above (and the phase values, if used as in other embodiments described below)) from the second signal detection section 8 are stored in the second memory 12b (SA1).

Next, for the amplitude values stored in the first memory 12a, a change in each sampling interval “ts” is derived as the first differential (=(A1(m+1)—A1m)) (SA2). For the amplitude values stored in the second memory 12b, a change in each sampling interval “ts” is derived as the second differential (=(A2(m+1)−A2m)) (SA3).

Subsequently, the average of the absolute value of differences between the first differentials and the second differentials (=|(A1(m+1)−A1m)−(A2(m+1)−A2m)|) is derived from the formula (2) above (SA4). Thereafter, the derived average is displayed in the display section 15 as the degree of discrepancy (SA5) for that position of the sensor 2.

A vicinity of the object 1 measured by the sensor 2 can be scanned by moving the sensor 2 to numerous locations in a systematic way and by conducing the above-described procedure for determining the degree of discrepancy at each sensor location. A position at which the sensor 2 detected electromagnetic waves having a temporal change substantially coinciding with the temporal change of the electromagnetic wave received by the interfered antenna 3 can be identified as a source or location of emission of the interfering electromagnetic waves.

Next, a specific example of the present embodiment will be explained.

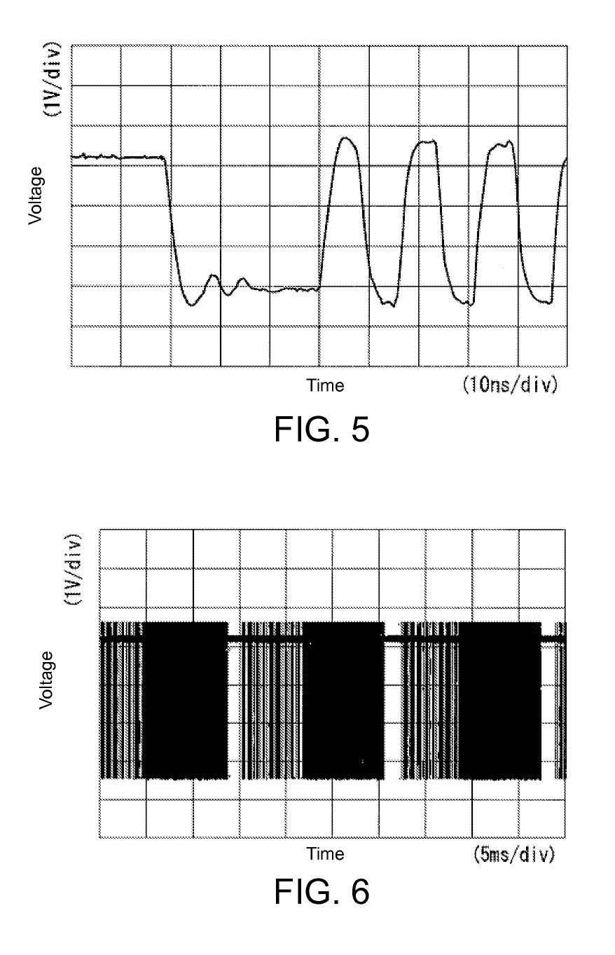

An electronic device 1, disposed near the antenna under interference 3, has a digital circuit with a base clock frequency of 27 MHz in this example. In a digital signal line such as an address bus line or a data bus line for a DRAM that is connected to the circuit, for example, a voltage waveform shown in FIG. 5 is observed. The voltage waveform is generated based on a frequency of 135 MHz, which is a quintuple of the base clock, and represents a logical value 0 or a logical value 1, corresponding to the digital information.

Between this DRAM and a semiconductor part such as an IC that is connected thereto in the surrounding area, a prescribed number of information sequences (bit sequence) is transmitted and received. This information is not continuously transmitted without breaks, but is transmitted intermittently in coordination with the respective semiconductor parts and the like. Therefore, during the information transmission, the logical value 0 and the logical value 1 repeatedly appear, corresponding to the information, and when the information transmission stops, the waveform is fixed to the logical value 0 or to the logical value 1. The respective periods in which the information transmission is performed and stops alternately appear at certain intervals, which vary in each of semiconductor blocks or terminals.

As shown in FIG. 6, when observing the voltage waveform in a longer time scale, the information transmission lasts for about 15 ms, and stops for about 1.5 ms, for example. That is, the information transmission is performed and stops repeatedly with a cycle of about 16.5 ms. In this example, this characteristic of changes with time is utilized to identify the interference source.

Such a digital signal associated with the DRAM may emit an electric field, a magnetic field, or both at a moment when transitioning from the logical value 0 to the logical value 1 or vise versa, and the energy thereof may propagate through space as an electromagnetic wave, and may be received by an antenna that is remote from the DRAM.

When the antenna is of an electric field type, it receives more electric field energy, and when the antenna is of a magnetic field type, it receives more magnetic field energy. Often, an antenna under influence of interference receives both electric field and magnetic field. The antenna under influence of interference may be of type that receives only one of the electric field and the magnetic field. In any case, when an antenna is disposed near the above-mentioned digital circuit (that contains or is disposed near semiconductor part such as DRAM), the antenna may receive the energy emitted from the digital signal. In such a case, the antenna is referred to as an antenna under interference. In the above-mentioned embodiment, the antenna 3 is the antenna under interference.

The energy of electric field, magnetic field, or both received by the antenna under interference is converted to electric power by the antenna, which is a basic function thereof, and is outputted to a coaxial connector. By connecting the coaxial connector of the antenna under interference to a coaxial connector of a measurement device through a coaxial cable having a characteristic impedance of 50Ω, the power signal received by the antenna under interference can be guided to the measurement device. This measurement device is the second signal detection section 8 in the above-mentioned embodiment. In the preceding stage of the second signal detection section 8, the mixer 6 is provided, and the duplexer 10 and the oscillator 9 are connected to the mixer 6. This circuit has a function of converting the frequency another frequencies; if the frequency of the oscillator 9 is set to B[MHz] when the power inputted into the mixer 6 from the antenna 3 has a frequency of A[MHz], for example, the frequencies of the output of the mixer 6 are A+B[MHz] and |A−B|[MHz]. The lower frequency |A−B| is selected and outputted using an appropriate filter, for example. That is, by appropriately setting the frequency of the oscillator 9, even when the frequency of the signal power inputted to the mixer 6 from the antenna 3 is high (i.e., outside of the range of the second signal detection section 8), the frequency can be down-converted to a frequency that can be handled by the second signal detection section 8 that is connected to the mixer 6 in the subsequent stage. For example, when the electric power received by the antenna 3 under interference has a frequency of 240 MHz, the frequency of the oscillator 9 is set to 170 MHz so that the frequencies of 240+170=410 MHz and 240−70=70 MHz can be obtained as the output frequencies of the mixer 6, and the lower output frequency is inputted into the second signal detection section 8 in the subsequent stage. In this case, the higher frequency component other than 70 MHz (i.e., 410 MHz) is filtered out (removed).

The second signal detection section 8 conducts sampling at a rate of 95 MSa/s, and converts the power signal inputted from the mixer 6 at intervals of 10.5 ns from analog to digital values. Then, by performing digital filtering (removal) and the quadrature demodulation, the amplitude and the phase of the digitized signal in a desired band are obtained. The processing section 12 retrieves the thus obtained amplitude digital value at prescribed sampling times (with a prescribed time interval “ts”), and store them in the second memory 12b, in order to determine the history of the changes in the amplitude digital value over time (the shape of the waveform). The digital values stored in the second memory 12b are transmitted to the discrepancy calculation section 13.

In this example, the size of the memory block may be set to 32768, and the total time for completing the retrieval of the amplitude digital values (or phase values in case of using phase values, as will be described below) for the determination of the temporal changes in the value may be set to 44 ms, for example. In other words, the temporal change in the amplitude digital values (i.e., the waveform) is observed for a period of 44 ms. By appropriately setting respective conditions such as sampling intervals and data quantity, this measurement period can be made longer than the period of the electromagnetic wave energy received by the antenna 3 under interference.

Since a duration of 44 ms is set for determining the waveform of the digitized amplitude data for the 32768 data slots, the data retrieval interval at which the processing section 12 retrieves (or store) the amplitude digital value from the second signal detection section 8 is 1.34 μs (=44 ms/32768). With respect to the first signal detection section 7, data retrieval from the first signal detection section 7 and storage of the digital value in the first memory 12a are conducted at the same timing. Thus, the date obtained by using the above-mentioned configuration has a total of 32768 amplitude data points each of which was converted to a digital value at intervals of 1.34 μs for both the first signal detection section 12a and the second signal detection section 12b.

As described above, in most cases, signals that propagate through digital signal lines such as address bus lines or data bus lines changes with time in manners that are respectively unique thereto, and therefore, by comparing these changes with a change in the interference signal over the course of time, an output terminal that outputs the signal emitting the interference electromagnetic waves can be identified among the output terminals of the IC more accurately and efficiently. This makes it possible to employ minimal countermeasures to prevent the emission of the interference electromagnetic waves, and therefore, the cost of the countermeasure can be reduced as compared with the conventional configurations.

Specific numeral values described above are merely examples, and are not limiting the scope of the present invention in any way. For example, in the above example, the base clock frequency was 27 MHz, but this is not limiting, needless to say. Depending on the specifications of the semiconductor part in question, the base clock frequency may be in a range of 32 kHz to 1 GHz, for example.

The multiplication factor of the clock frequency may be 3, 5, or so, but may take other numbers in accordance with the specifications of the semiconductor parts.

The periodicity of the information transmission by DRAM or the like that could cause the undesired interference is not limited to the above example, and is typically set in accordance with the specifications of the semiconductor parts.

The output of the mixers 5 and 6 is not limited to 70 MHz, and can be appropriately set in accordance with the specifications of the first and second signal detection sections 7 and 8, which are used in the subsequent stage.

The sampling of the first and second signal detection sections 7 and 8 is not limited to 95 MSa/s, and can be appropriately set in accordance with the specifications of the A/D converter in use.

In the digital signal processing of the computer device 11, the frequency and the bandwidth can be adjusted to correspond to interference conditions under measurement.

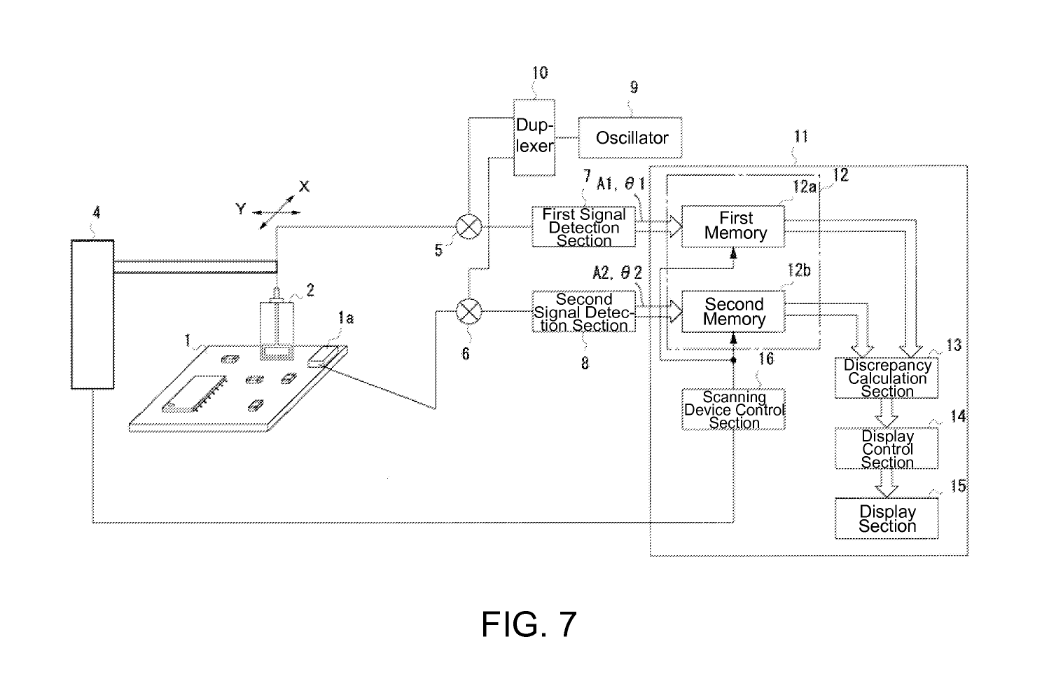

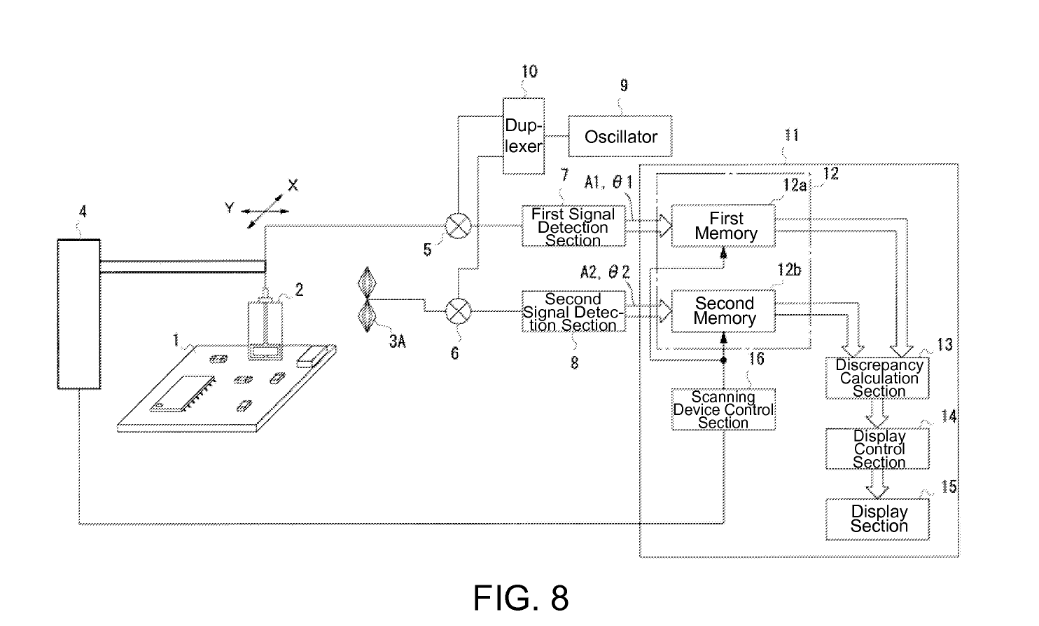

FIGS. 7 and 8 show modifications of the above-described specific configuration. As shown in FIG. 7, an antenna 1a within the electronic device 1 may be receiving interference caused by other part of the device 1. In such a case, the antenna 1a within the device 1 may be used as the antenna 3 that receives the interference waves. Alternatively, as shown in FIG. 8, an EMI measurement antenna 3A may be used as the antenna 3 that receives the interference waves.

Next, Embodiment 2 of the present invention will be explained.

The device configuration of Embodiment 2 is substantially the same as that of Embodiment 1 above. Embodiment 2 differs from Embodiment 1 in that the degrees of discrepancy as the measurement results are displayed in the display section 15 as a map. That is, the degrees of discrepancy are categorized into a plurality of levels, and using different display colors or shades for the respective levels, the degrees of discrepancy on the plane (XY plane) of the electronic device 1 are displayed on a monitor screen of the display section 15.

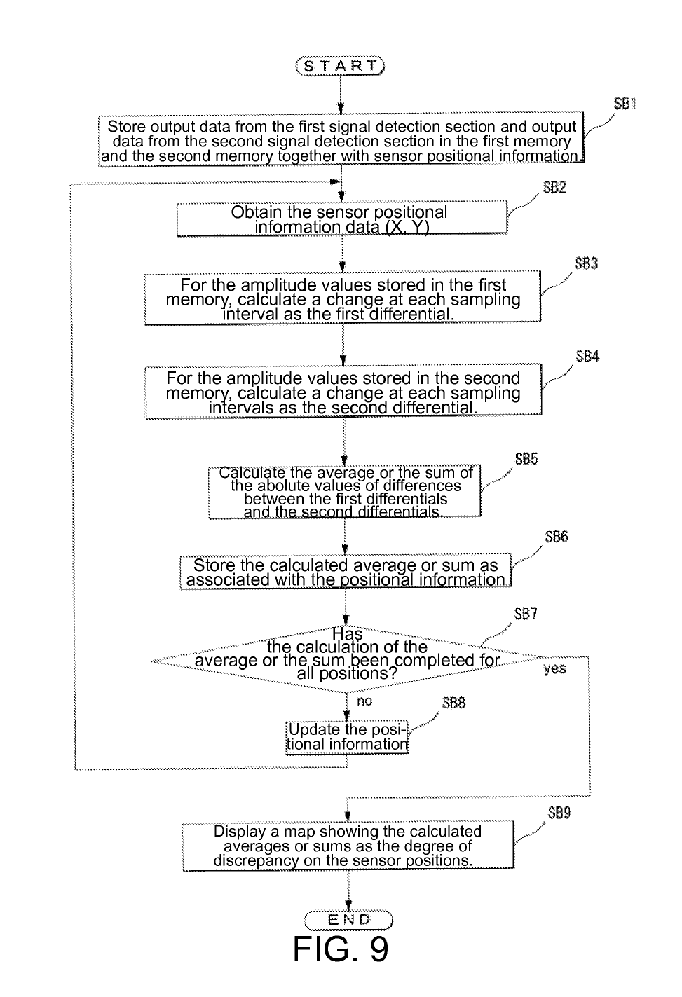

An operation of the computer device 11 in this case will be explained with reference to a flowchart shown in FIG. 9.

When the measurement is started, the computer device 11 performs the following steps SB1 to SB9, while changing the positions of the sensor 2.

That is, for a give position of the sensor 2, the positional information of the sensor 2 and the output data (the amplitude values described above (and the phase values, if used as in other embodiments described below)) from the first signal detection section 7 are stored in the first memory 12a, and the positional information of the sensor 2 and the output data described above (the amplitude values (and the phase values if used as in other embodiments described below)) from the second signal detection section 8 are stored in the second memory 12b (SB1).

After all the measurement data for the determination of the waveform for a particular sensor position are stored in the first memory 12a and the second memory 12b, the positional information stored in the first memory 12a and the second memory 12b is read out (SB2). Next, for that particular sensor position, a change in the amplitude values stored in the first memory 12a at each sampling interval “ts” is derived as the first differential ((A1(m+1)−A1m)) (SB3). For the amplitude values stored in the second memory 12b, a change at each sampling interval “ts” is derived as the second differential ((A2(m+1)−A2m)) (SB4).

Subsequently, an average of the absolute values of differences between the first differentials and the second differentials |(A1 (m+1)−A1m)−(A2 (m+1)−A2m)| is derived from the formula (2) above (SB5). Thereafter, the derived average value is stored in a not-shown memory such as a hard disk as the degree of discrepancy as associated with the positional information representing that particular position of the sensor 2 (SB6).

Next, whether or not the calculation of the average (the degree of discrepancy) has been completed for all of the positions measured by the sensor 2 on the XY plane is determined (SB7). If the calculation of the average (degrees of discrepancy) has not been completed for all of the positions measured, the positional information is updated (SB8), and the process goes back to the step SB2. That is, the steps from SB2 to SB6 are repeated for a different position of the sensor 2. Here, the order and the sequence of the steps and movement of the sensor 2 described above can be appropriately changed depending on needs. For example, the memories 12a and 12b can store the amplitude data (and the phase data if used in combination as in other embodiments) for all the positions of the sensor 2 before conducting the data processing in steps SB2 to SB6. Alternatively, at each physical position of the sensor 2, steps SB1 to SB6 can be performed in substantially real time while the sensor 2 moves across the measurement plane.

When the calculation of the averages, i.e., the calculation of the degrees of discrepancy, for all of the positions measured has been completed, the calculated average values associated with the positional information of the sensor 2 on the XY plane are displayed in the display section 15 as the degrees of discrepancy by using different colors for the respective levels of the degrees of discrepancy as described above (SB9).

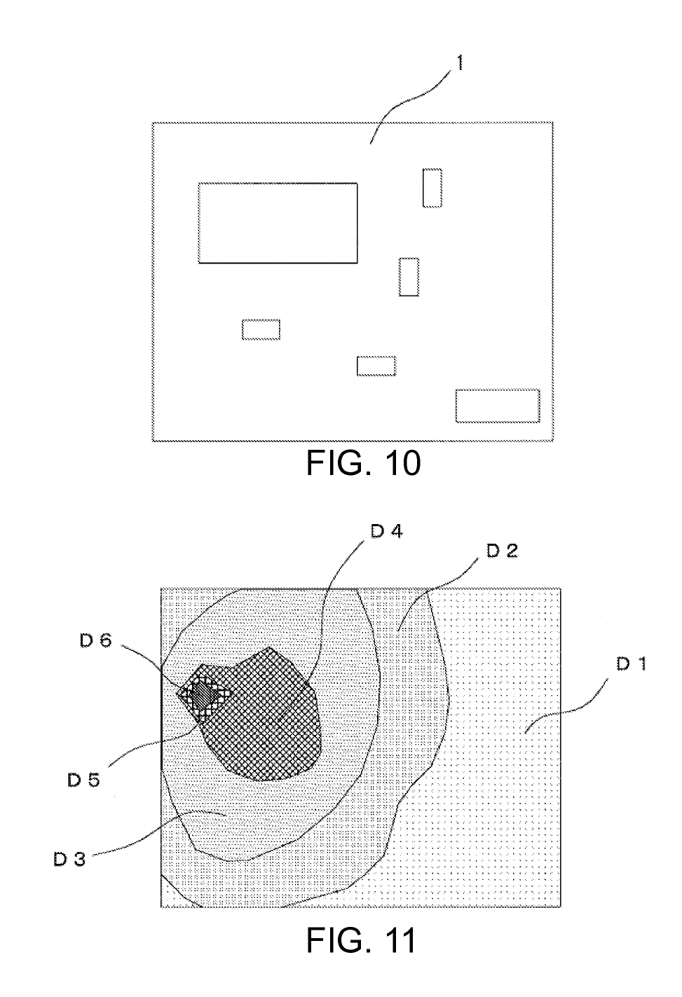

For example, when the electronic device 1 has a plan view shape shown in FIG. 10, the degrees of discrepancy are displayed with different colors or shades as a map shown in FIG. 11. In FIG. 11, six different levels D1 to D6 are shown in different colors or shades, respectively, with the level D1 having the greatest degree of discrepancy and the level D6 having the smallest degree of discrepancy, i.e., D1>D2>D3>D4>D5>D6. Since D6 has the smallest degree of discrepancy, it can be determined that the source of the interference electromagnetic waves is present at a position displayed as the level D6.

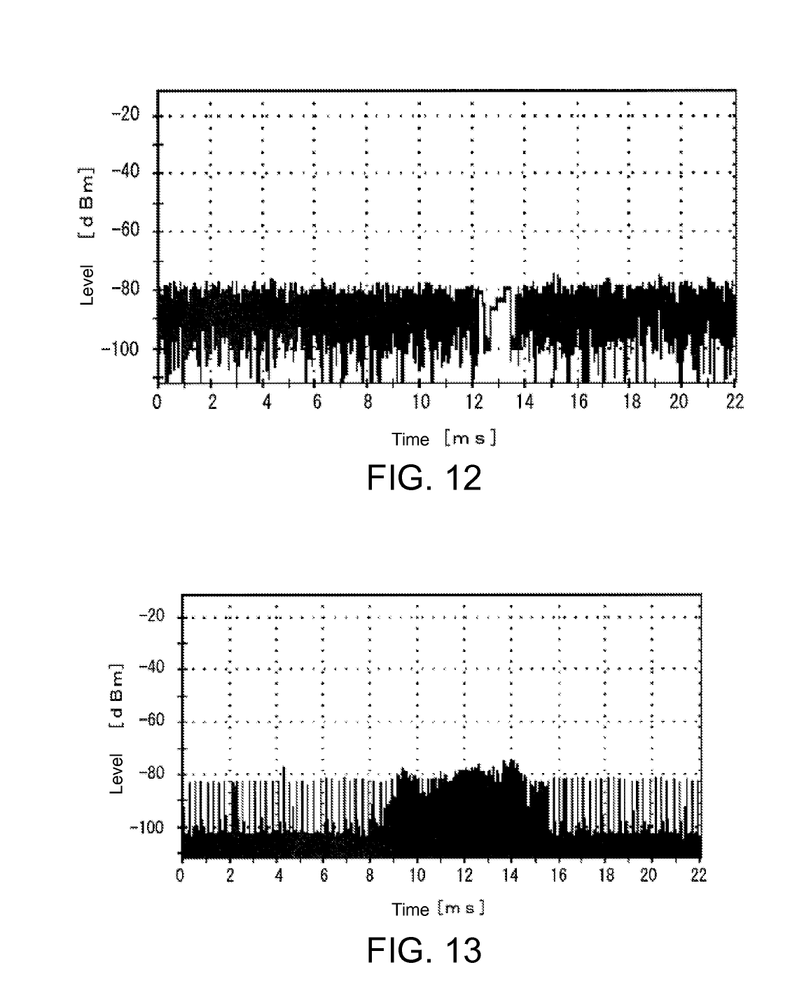

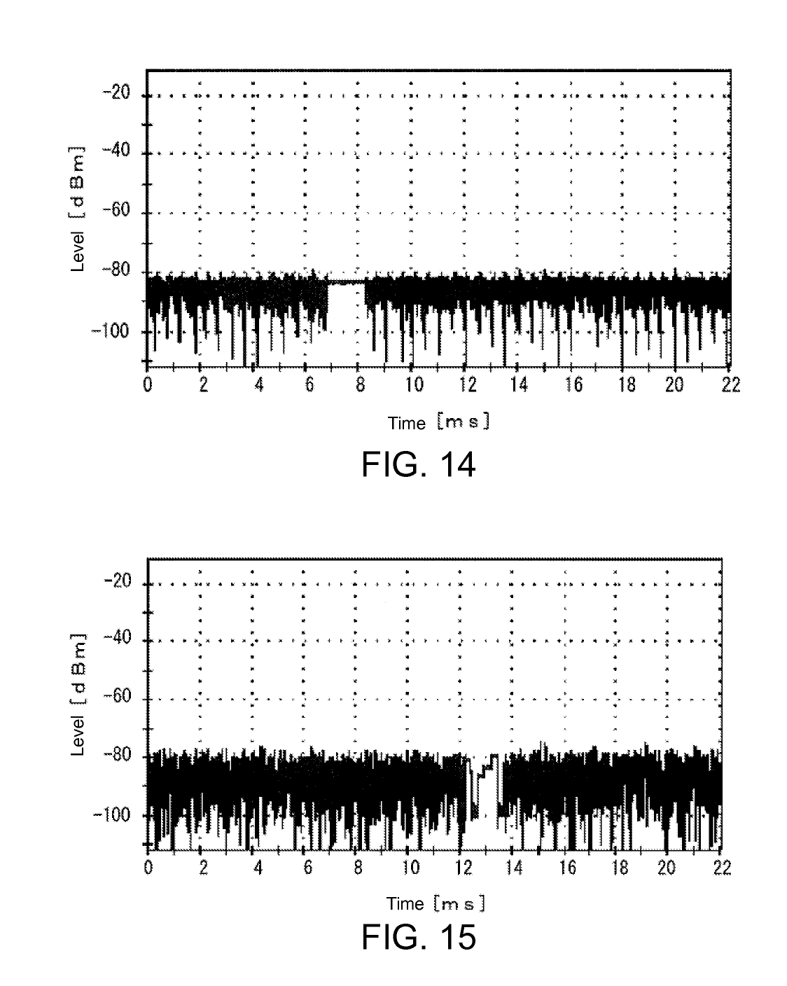

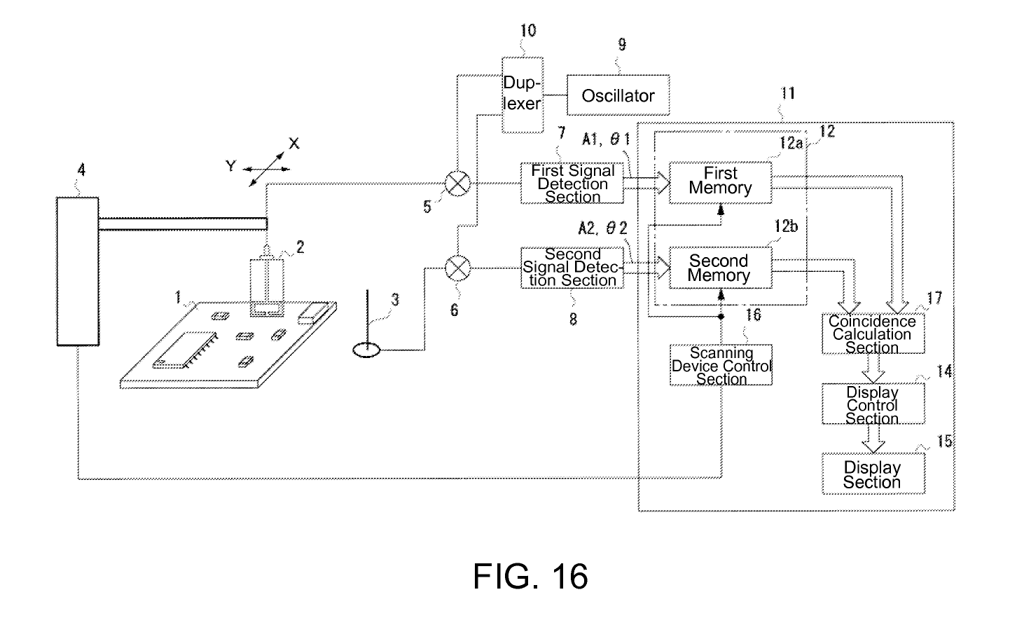

FIG. 12 shows an example of the temporal waveform of the amplitude of the signal power derived from the antenna 3 that is receiving the interference electromagnetic waves, for example. Here, in FIG. 12, the horizontal axis denotes the time, and the vertical axis denotes the amplitude of the signal power. FIG. 13 shows a waveform of the signal amplitude at a position in the level D3 area. FIG. 14 shows a waveform of the signal amplitude at a position in the level D4 area. FIG. 15 shows a waveform of the signal amplitude at a position in the level D6 area. As shown in the figures, the waveform of the signal amplitude at a position of the sensor 2 in the level D6 area substantially coincides with the waveform of the signal amplitude received by the antenna 3. This means that the source of the interference electromagnetic wave is present in the area displayed as the level D6.

As described above, according to the present embodiment, a vicinity of the object 1 to be measured is scanned by the sensor 2 by moving the sensor 2 in a predetermined sensing area over the object 1, the detection signals thereof and the signal received by the antenna 3 are compared, and the degrees of discrepancy therebetween are displayed as a map. By looking at this map, a position of the sensor 2 at which the electromagnetic wave detected by the sensor 2 shows a temporal change substantially coinciding with the temporal change of the electromagnetic wave received by the antenna 3 is identified as the location of the source the interfering electromagnetic waves.

Next, Embodiment 3 of the present invention will be explained.

In Embodiment 3, the phrase values described above are used in the determination of the location of the source of the interfering electromagnetic wave. That is, a device of Embodiment 2 identifies, as the location of a source of interference electromagnetic waves, a position near a sensor position at which a difference between a phase of electromagnetic wave received by the antenna under interference 3 and a phase of electromagnetic wave detected at the sensor position by the sensor, which moves across a vicinity of the electronic device emitting the interference electromagnetic wave, remains as substantially the same value over a prescribed measurement period. Here, the phase difference between the received signals of the electromagnetic waves, which are inputted into two input sections, is determined, and the stability in time of the phase difference is used as the degree of coincidence in order to identify the source location.

Based on the stability in the difference between the phase of the power signal received by the antenna under interference and the phase of the power signal detected by the electromagnetic wave sensor, whether these signals are the same signal having coherency or not can be determined.

Because signals of the electromagnetic waves emitted from the same source generally have coherency, the phase difference between two different signals from the same source, which are the signal received by the electromagnetic wave sensor located near the source and the signal of the electromagnetic wave received by the antenna under interference, will assume substantially the same value over time. Even though signals have the same frequency, if the signals are emitted from different sources, the respective signals are out of phase from each other in a somewhat random manner, and the phase difference therebetween constantly changes. This property makes it possible to identify the location of the source of the signal.

If the intensity of this signal significantly changes with time, during the time when the signal is large, the stable phase difference can be measured, but during the time when the signal is small, the phase difference becomes unstable because thermal noise from the measurement device and the like is included in the measurement results. For this reason, if the phase difference between two signals remains substantially the same for a prescribed period of time, instead of the entire time of the measurements, the two signals can be determined as originating from the same source.

When the phase difference between the two power signals are measured for a prescribed period of time, if these signals are not synchronized at all, in other words, do not coincide with each other at all, the values of the phase difference are evenly distributed throughout the range of ±180 degrees. If the phases of signals coincide with each other, a range of the variations in phase difference values becomes more concentrated to a vicinity of a specific value. The degree of coincidence is determined on the basis of the amount of this variation. This variation can be represented by the variation width, the half width, the difference between the greatest value and the smallest value in the histogram, or the like, for example. When the variation width of the values of the phase difference is within a range of ±5 degrees, for example, it can be determined that the two signals originate from the same source.

FIG. 16 is a block diagram showing an electric circuit of an electromagnetic interference source identification device according to Embodiment 3 of the present invention.

In the figure, the same reference characters are given to the same components as those of Embodiment 1 above, and descriptions thereof other than the following description are omitted.

In Embodiment 3, the first signal detection section 7 having a configuration similar to that of the second signal detection section 8 is provided. The first signal detection section 7 and the second signal detection section 8 have the same circuit configuration, and coaxial cables that connect the duplexer 10 to the mixer 5 and to the mixer 6, respectively, have the same length. A coaxial cable that connects the sensor 2 to the mixer 5 and a coaxial cable that connects the antenna 3 to the mixer 6 have the same length. Further, a coaxial cable that connects the mixer 5 to the first signal detection section 7 and a coaxial cable that connects the mixer 6 to the second signal detection section 8 have the same length. This way, the phase of the signal inputted into the first signal detection section 7 and the phase of the signal inputted into the second signal detection section 8 maintain the same conditions. That is, the phase relationship between the signal power inputted into the first signal detection section 7 and the signal power inputted into the second signal detection section 8 can be maintained to be the same as the phase relationship between the signal power detected by the sensor 2 and the signal power received by the antenna 3. Also, in the sampling by the first and second signal detection sections 7 and 8, by performing the digital-conversion in the two sections at the same time so as not to cause phase differences, the same phase relationship between the two input powers can be maintained after digitalization.

That is, the digital data representing the phases of the respective signals can be obtained without changing the phase relationship between the signal power received by the antenna under interference 3 and provided through the second signal detection section 8 and the signal power received by the sensor 2 and provided through the first signal detection section 7.

Embodiment 3 differs from Embodiment 1 in that the programs of the computer device 11 were modified such that, in Embodiment 3, the degree of coincidence is calculated from the digital values θ1 and θ2 of the phases of the respective signal powers, instead of calculating the degree of discrepancy using the digital values A1 and A2 of the amplitude of the signal powers as in Embodiment 1. For each of the positions of the sensor 2, at sampling interval “ts,” the digital values θ1 and θ2 of the phases of the respective signal powers values are retrieved from the first and second signal detection sections 7 and 8 in the same timing, respectively, for a predetermined duration of time, and are stored in the memories 12a and 12b, respectively. In Embodiment 3, a coincidence calculation section 17 is provided in place of the discrepancy calculation section 13 used in Embodiment 1.

That is, for a particular position of the sensor 2 (which can be determined from the positional information of the sensor 2), the coincidence calculation section 17 in the present embodiment reads out the digital values θ1 and θ2 of the phase values of the signals from the first memory 12a and from the second memory 12b, respectively, and using the read-out phase digital values θ1 and θ2, derives the stability of the phase difference over the course of time between the phase of the signal power detected by the sensor 2 and the phase of the signal power received by the antenna 3 in order to calculate the degree of coincidence for that position of the sensor 2.

That is, with respect to a particular position of the sensor 2, in the first memory 12a, the amplitude values A1=(A11, A12, . . . A1n) of the signal power detected by the sensor 2 and the phase values θ1=(θ11, θ12, . . . θ1n) thereof are stored, and in the second memory 12b, the amplitude values A2=(A21, A22, . . . A2n) of the signal power received by the antenna 3 and the phase values θ2=(θ21, θ22, . . . θ2n) thereof are stored. In the present embodiment, these amplitude values A1, A2 are not used, and only the phase values θ1, θ2 are used. Thus, the memories 12a and 12b may store only the respective phase values and can be configured not to store the amplitude values. The signal used by the quadrature demodulators in the signal detection sections 7 and 8 is used as a reference for the phases θ1, θ2. Therefore, generally, the phase difference therebetween is not fixed to a specific value. However, if the two signal inputs have coherency, the phase difference between these two signals “θd=θ1−θ2” remain substantially the same over time.

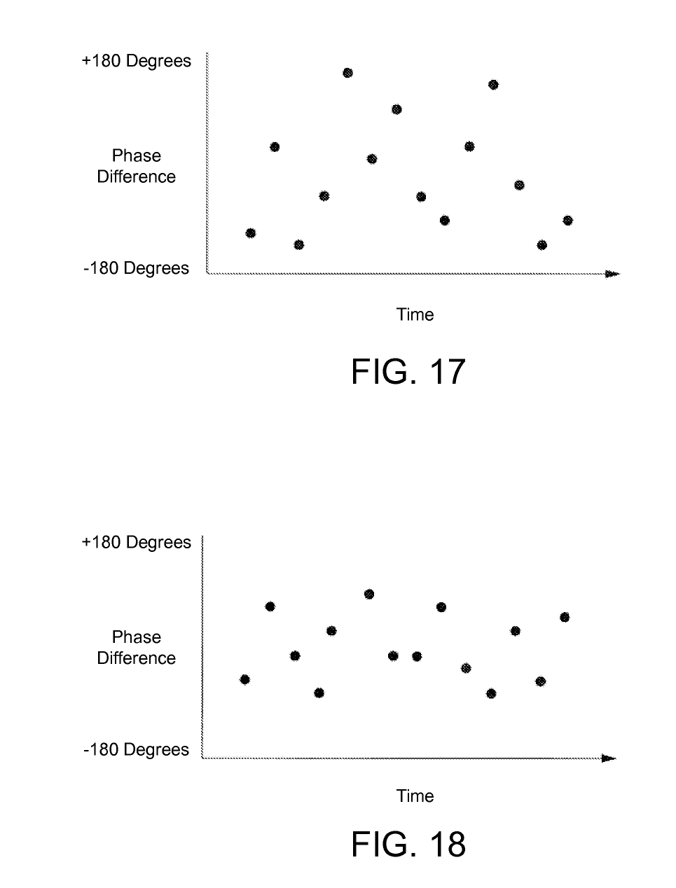

For example, the value of the phase difference between the phase value θ1 (first phase digital value) of the signal power stored in the first memory 12a and the phase value θ2 (second phase digital value) of the signal power stored in the second memory 12b, i.e., the phase difference “θd=θ1−θ2,” changes with time as shown in FIGS. 17 to 19, depending on the positions of the sensor 2.

The measurement time can be represented by “sampling interval “ts”×sampling size “n” (n is a positive integer).” As in the case of the above-described embodiments, it is preferable that the sampling interval “ts” and the sampling size “n” be appropriately set in accordance with the noise to be measured. The degree of coincidence can be calculated from the complete set of measurement data taken for a prescribed duration of time or from a subset of that data.

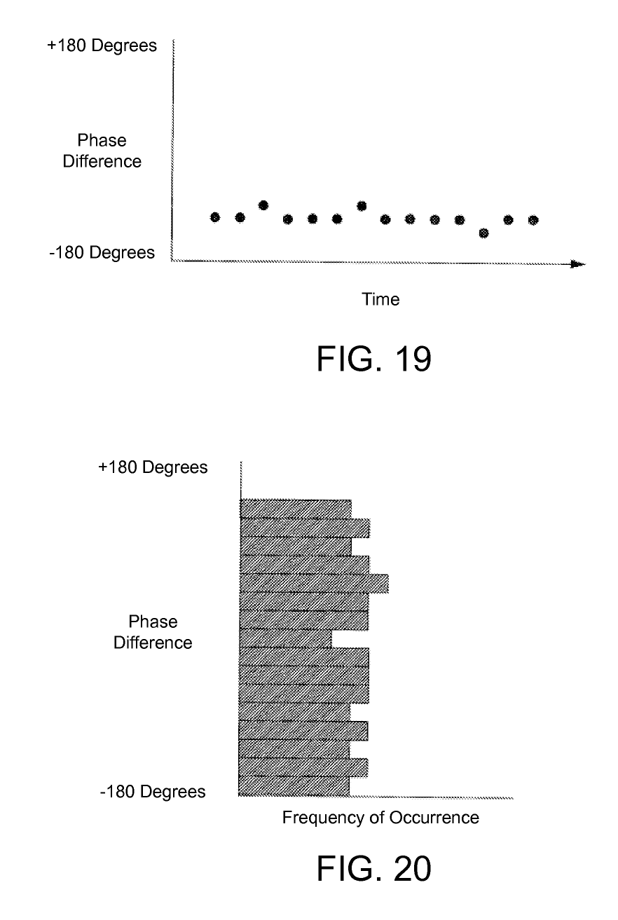

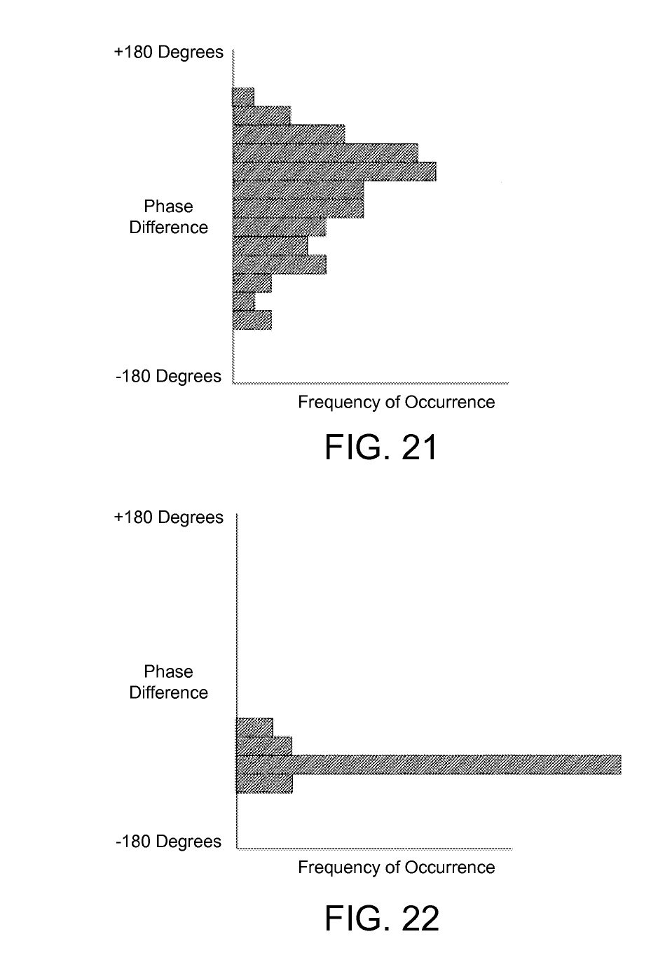

In the present exemplary embodiment, for each of the positions of the sensor 2, the degree of coincidence is obtained by making a histogram of respective phase differences θd to derive frequencies of occurrence thereof, and by identifying a phase difference value having the highest frequency of occurrence among the frequencies of the respective phase differences θd. For example, the degree of coincidence may be expressed by the difference between the highest frequency of occurrence and a frequency of occurrence in the case where the phase differences are completely randomly (in other words, uniformly) distributed. As the degree of coincidence becomes greater, the phase of the signal power detected by the sensor 2 and the phase of the signal power detected by the antenna 3 have the higher coherency. The position of the sensor 2 at which the higher coherency is observed between the two detected signals can be regarded as the location of the source of the electromagnetic interference. This way, the source of the interference electromagnetic waves can be identified from the position of the sensor 2. For example, FIG. 20 shows a frequency distribution when the phase difference changes as shown in FIG. 17, FIG. 21 shows a frequency distribution when the phase difference changes as shown in FIG. 18, and FIG. 22 shows a frequency distribution when the phase difference changes as shown in FIG. 19. As shown in the figures, the more the phase differences θd converges to a specific value, the more stability in time the difference between the phase of the signal power detected by the sensor 2 and the phase of the signal power received by the antenna 3 becomes, which means that the coherency therebetween is higher. In this example, the degree of coincidence may be defined as a difference between the highest frequency of occurrence and a frequency of occurrence in the case where the phase differences are hypothetically distributed uniformly. That is, the latter frequency of occurrence is used as the baseline. The frequency of occurrence for the randomly (uniformly) distributed phase differences is defined as “the total number of measurements/number of divisions in the phrase difference range.” For example, the baseline phase difference as defined is 100, when the sampling size is 3600 points and the phase difference range of +−180 degrees is divided into 10-degree increments.

Alternatively, other definitions can be used for the degree of coincidence that represents the absence of change in the phase difference values over the course of time. For example, the degree of coincidence can alternatively be defined by the following formula (3), where the sampling size is “n.”

$$\begin{matrix}Formula ( 3 ) & \\ Degree of coincidence = \frac{1}{{\sum }_{m = 1}^{n} \vert ( {θ}_{1 m} - {θ}_{2 m} ) - ( {θ}_{1 m + 1} - {θ}_{2 m + 1} ) \vert} & ( 3 )\end{matrix}$$

Alternatively, the degree of coincidence may be defined by the following formula (4).

$$\begin{matrix}Formula ( 4 ) & \\ Degree of coincidence = \frac{1}{( {\sum }_{m = 1}^{n} \vert ( {θ}_{1 m} - {θ}_{2 m} ) - ( {θ}_{1 m + 1} - {θ}_{2 m + 1} ) \vert ) \times n} & ( 4 )\end{matrix}$$

The display control section 14 receives the degree of coincidence calculated by the coincidence calculation section 17 and the positional information of the sensor 2 corresponding to the degrees of coincidence from the coincidence calculation section 17, and displays the positional information of the sensor 2 (i.e., the position of the sensor 2 for which the degree of coincidence is calculated) and the degree of coincidence in the display section 15.

In the present embodiment, effects similar to those of Embodiment 1 above can be obtained.

In displaying the measurement results, it is possible to display the degree of coincidence at the then current position of the sensor 2 only, or alternatively, the results may be shown as a table showing all of the positions of the sensor 2 and the associated degrees of coincidence. It is preferable to appropriately set the display format.

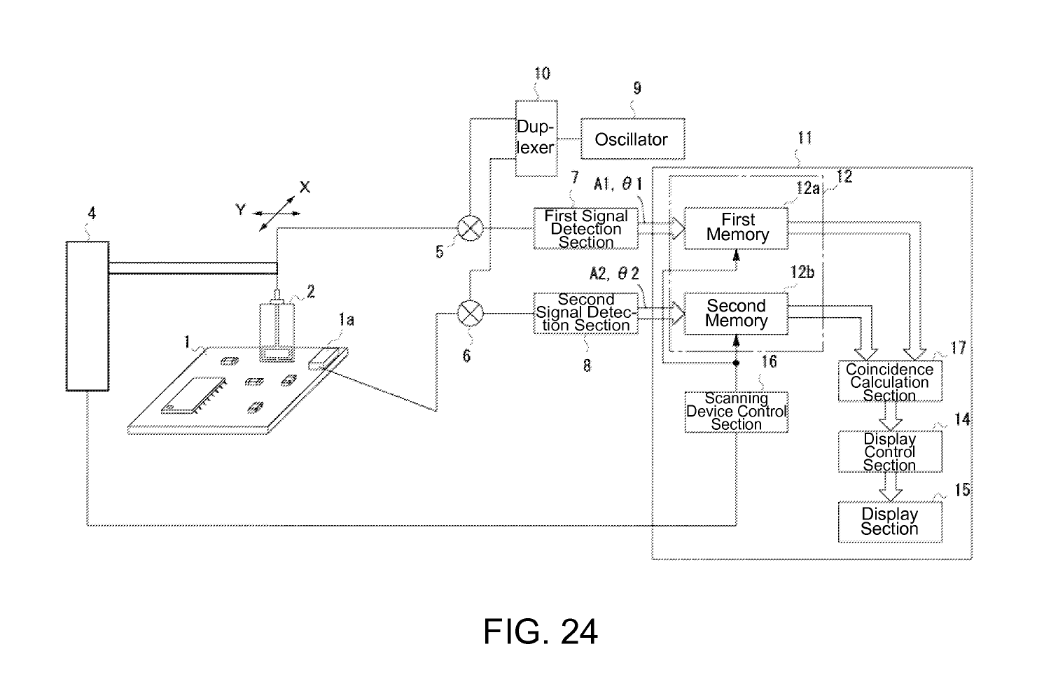

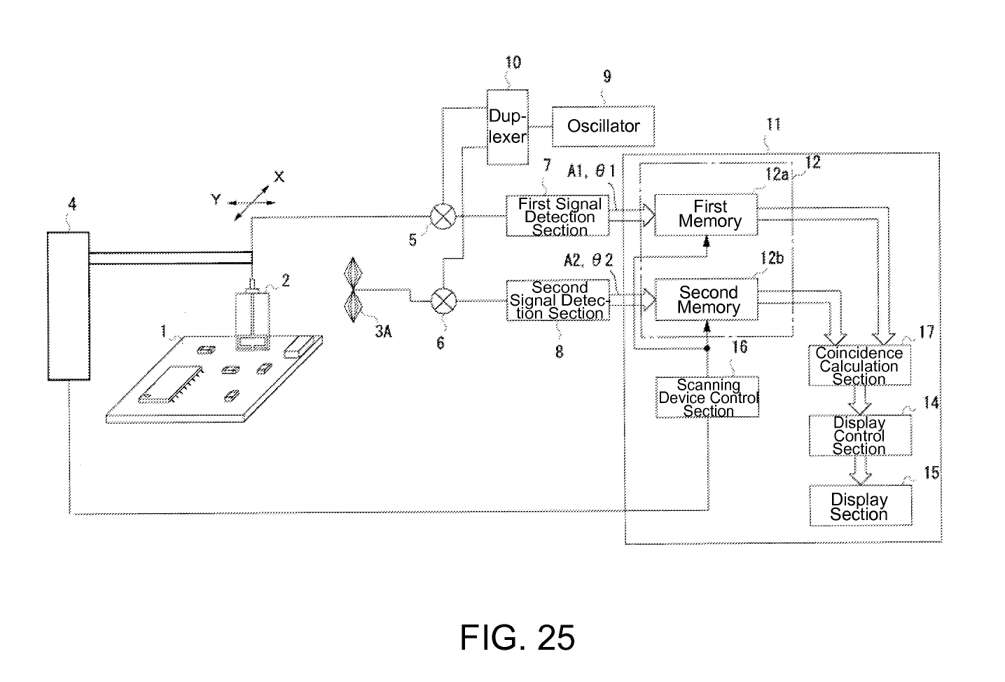

As shown in FIG. 24, in the case of the intra-system EMC, the antenna 1a of the electronic device 1 under interference may be used as the antenna 3 for receiving the interference waves. Alternatively, as shown in FIG. 25, the EMI measurement antenna 3A may be used as the antenna 3 for receiving the interference waves.

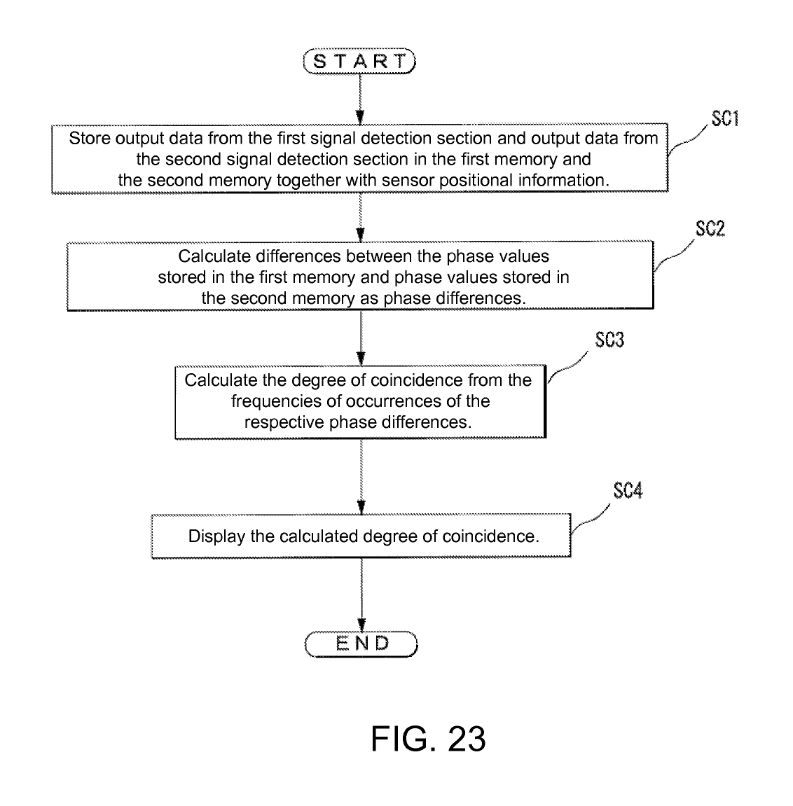

Next, an operation of an electromagnetic interference source identification device according to the present embodiment will be explained with reference to a flowchart shown in FIG. 23.

When the measurement is started, the computer device 11 performs the following steps SC1 to SC4 for each of the positions of the sensor 2.

That is, the positional information of the sensor 2 and output data (the phase values described above (and the amplitude values, if used in other embodiments described above and below) from the first signal detection section 7 are stored in the first memory 12a, and the positional information of the sensor 2 and output data (the phase values (and the amplitude values, if used in other embodiments described above and below)) from the second signal detection section 8 are stored in the second memory 12b (SC1).

Next, for each of the sampled data, the difference (phase difference θd) between the phase values θ1 stored in the first memory 12a and the phase values θ2 stored in the second memory 12b is calculated (SC2).

Thereafter, by deriving the frequencies of the phase differences θd, which were derived in SC2, the degree of coincidence is calculated (SC3). Next, the calculated degree of coincidence is displayed in the display section 15 (SC4).

As described, according to the present embodiment, for each of the positions of the sensor 2, which is moved across a vicinity of the object 1 the phase of the detection signal by the sensor 2 and the phase of the signal received by the antenna 3 are compared and their behavior over a prescribed period of time (for 44 ms, for example) is evaluated. And a position of the sensor 2 at which the phase difference of these two signals does not vary much over time—i.e., the sensor position at which coherency between the electromagnetic wave detected by the sensor 2 and the electromagnetic wave received by the antenna 3 is high—is identified as the location of the source of the interference electromagnetic wave.

Therefore, in the present embodiment, effects similar to those of Embodiment 1 above can be obtained.

In the present embodiment, because presence or absence of the coherency is determined by comparing the phases of the respective signals, the source is identified in a manner different from those in Embodiments 1 and 2 where temporal changes of the amplitude of the signals are compared. These different methods can be combined such that the source of the interference waves can be identified more accurately. For example, an average of the degree of discrepancy expressed in formula (2) and an inverse of the degree of coincidence expressed in formula (4) (with appropriate normalization or weighted average) may be calculated to derive a combined degree of discrepancy for improved source identification. Other suitable combinations are possible.

Next, Embodiment 4 of the present invention will be explained.

The device configuration of Embodiment 4 is substantially the same as that of Embodiment 3 above, and a difference between Embodiment 3 and Embodiment 4 is that the degrees of coincidence of the measurement results are displayed in the display section 15 as a map. For example, the degrees of coincidence are categorized into a plurality of levels, and using different display colors or shades for the respective levels, the degrees of coincidence on the plane (XY plane) of the electronic device 1 are displayed on a monitor screen of the display section 15.

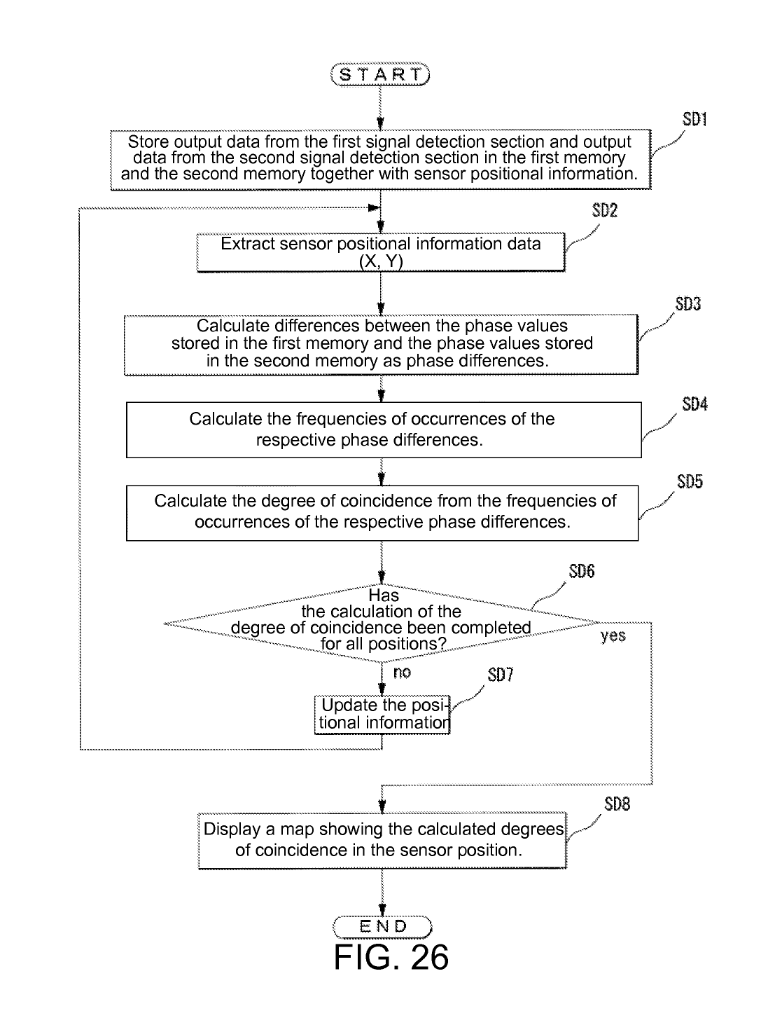

An operation of the computer device 11 in this case will be explained with reference to a flowchart shown in FIG. 26.

When the measurement is started, the computer device 11 performs the following steps SD1 to SD8, while changing the positions of the sensor 2.

First, for a given position of the sensor 2, the positional information of the sensor 2 and output data (the phase values described above (and the amplitude values, if used in combination)) from the first signal detection section 7 are stored in the first memory 12a, and the positional information of the sensor 2 and output data (the phase values described above (and the amplitude values, if used in combination)) from the second signal detection section 8 are stored in the second memory 12b (SD1).

After storing all the measurement data for a prescribed period for that particular position of sensor 2 in the first memory 12a and in the second memory 12b, the positional information stored in the first memory 12a and the second memory 12b is read out (SD2), and the difference (phase differences θd) between the phase values θ1 stored in the first memory 12a and the phase values θ2 stored in the second memory 12b is calculated for that positional information representing the particular position of the sensor 2 (SD3).

Thereafter, the frequencies of occurrence of the phase differences θd are calculated (SD4) and, in this example, the value of the highest frequency of occurrence is identified as the degree of coincidence and is stored as in a not-shown memory section such as a hard disk, as associated with that position of the sensor 2. (SD5).

Next, whether or not the degree of coincidence (i.e., the highest frequency of occurrence in this example) has been calculated for all of the positions of the sensor 2 on the XY plane is determined (SD6), and if the degree of coincidence has not been calculated for all of the positions of the sensor 2, the positional information is updated (SD7), and the process goes back to the step SD2. Here, the order and the sequence of the steps and movement of the sensor 2 described above can be appropriately changed depending on needs. For example, the memories 12a and 12b can store the phase data (and the amplitude data if used in combination as in other embodiments) for all the positions of the sensor 2 before conducting the data processing in steps SD2 to SD5. Alternatively, at each physical position of the sensor 2, steps SD1 to SD5 can be performed in substantially real time while the sensor 2 moves across the measurement plane.

When the calculation of the degree of coincidence for all of the positions measured has been completed, the degrees of coincidence corresponding to the respective positions of the sensor 2 on the XY plane are displayed in the display section 15 by using different colors or shades for the respective levels as described above (SD8).

For example, when the electronic device 1 has a plan view shape shown in FIG. 10, the degrees of coincidence are displayed with different colors or shades as a map shown in FIG. 11. In FIG. 11, six different levels D1 to D6 are shown in different colors or shades, respectively, with the level D6 having the greatest degree of coincidence and the level D1 having the smallest degree of coincidence, i.e., D1<D2<D3<D4<D5<D6. In this case, the source of the interference electromagnetic waves is determined to be located in an area displayed as the level D6.

As described, according to the present embodiment, by moving the sensor 2 in a vicinity of the object 1 to be measured to scan the vicinity, and by comparing the detection signal thereof and the signal received by the antenna 3, the degrees of coincidence therebetween are displayed as a map. Therefore, by looking at the displayed map, a position of the sensor 2 at which the coherency between the electromagnetic wave detected by the sensor 2 and the electromagnetic wave received by the antenna 3 is high is identified. And it can be determined that the source of the interference electromagnetic wave is located at that position or an area very close to it.

Therefore, in the present embodiment, effects similar to those of Embodiment 1 above can be obtained.

The method of finding out the location of the source of interference electromagnetic waves in each of the embodiments described above may be used alone, or a plurality of methods can be combined in order to identify the source. Also, in order to address the randomness that often occurs in the noise measurement, it is also possible to employ statistical processing such as performing the measurement repeatedly under the same conditions for multiple times to obtain the average value or standard deviation of the degrees of discrepancy or the degrees of coincidence. Moreover, in each of the above embodiments, the frequency at which the quadrature demodulation is performed at the first and second detection sections 7 and 8 and the frequency of the oscillator 9 used for down-converting the frequencies of the signals from the sensor 2 and the antenna 3 can be appropriately chosen, based on the operation condition and/or specifications of the device 1 which is suspected to be causing electromagnetic interference, for example.

By using the scanning device 4 with two axes (X axis and Y axis orthogonal to each other) or with three axes (X axis, Y axis, and Z axis orthogonal to each other) that moves the sensor 2 detecting electromagnetic waves (this could include local field detection), and by performing such measurements while changing the position of the sensor 2, the degrees of discrepancy or the degrees of coincidence can be displayed at the respective positions (sensor positions) in a map. This way, the source and/or the location of the source of the interference electromagnetic waves can be identified more accurately than a conventional technology.

As described above, in the respective embodiments above, it is possible to identify a source of interference electromagnetic waves having signal power that coincidences with noise signal power outputted from the antenna that receives the interference electromagnetic wave in terms of temporal change, coherency, or the like. Therefore, a source of interference electromagnetic waves for the intra-system EMC or an electromagnetic wave source of fundamental noise that results in unwanted emission EMI can be identified, which makes it possible to take an effective countermeasure against the EMC problem.

In cases of the intra-system EMC, an antenna disposed inside of the subject device under measurement can be used to detect the signal with which the signal detected by the sensor 2 is compared in order to identify the source or the location of the source of the interference. Also, when studying unwanted emission EMI, a 10 m anechoic chamber or the like can be used to avoid any influence or to avoid noise from external interference sources. This way, a source of the EMI can be identified more accurately.

A shielded loop antenna was used as the sensor 2 in the examples above, but the present invention is not limited to such, and it is apparent that the same or similar effects can be obtained with other antennas such as a mono-pole antenna.

By creating a computer readable information recording medium such as a floppy (trademark) disk, a CD, or a DVD that has computer programs recorded therein to instruct the computer device to perform the operations described in the respective embodiments above, any computer devices can be effectively used in a manner similar to the computer device 11.

By scanning a vicinity of an electronic device that emits interference electromagnetic waves by a sensor, and by comparing the signal power of the electromagnetic wave detected by the sensor at respective sensing positions with the signal power outputted from an antenna that is receiving the interference electromagnetic waves, a source and/or the location of the source of the interference electromagnetic waves can be identified based on the sensor position. This makes it possible to identify a source and/or the location of the source of interference electromagnetic waves in the intra-system EMC or an electromagnetic wave source of fundamental noise that results in unwanted emission EMI, and as a result, an effective countermeasure can be taken for the EMC problem.

It will be apparent to those skilled in the art that various modification and variations can be made in the present invention without departing from the spirit or scope of the invention. Thus, it is intended that the present invention cover modifications and variations that come within the scope of the appended claims and their equivalents. In particular, it is explicitly contemplated that any part or whole of any two or more of the embodiments and their modifications described above can be combined and regarded to fall within the scope of the present invention. In the above examples, the term “degree of coincidence” and the term “degree of discrepancy” are used to express the degree of similarity between the two power signals. Typically, in the former terminology, the higher the value is, the more similar the two signals are, and in the latter terminology, the lower the value is, the more similar the two signals are. But these terms, as used in this specification and claims, broadly encompass any index or numbers that can represent the similarity or dissimilarity of the two signals, and can be interchangeably used to denote the broad concept regardless of whether higher values indicate similarity or dissimilarity.

What is claimed is:

1. A device for identifying a location of electromagnetic interference source, comprising:
a sensor disposed to be movable in a vicinity of a subject electronic device that is suspected to emit interfering electromagnetic wave, the sensor receiving near-field electromagnetic field emitted from the subject electronic device, and outputting a signal power of said received near-field electromagnetic field as first signal power;
a first signal detection section that receives the first signal power outputted from the sensor, the first signal detection section outputting a first digital value that corresponds to an amplitude of said first signal power;
a second signal detection section that receives a signal power of interference electromagnetic wave received by an electronic device under interference as second signal power, the second signal detection section outputting a second digital value that corresponds to an amplitude of said second signal power;
a processing and calculation section that receives the first digital values and the second digital values obtained for a prescribed period of time for a particular position of the sensor, the processing section calculates a change in the amplitude of the first signal power and a change in the amplitude of the second signal power, respectively, over the prescribed period of time for the particular position of the sensor, the processing section further comparing the calculated change in the amplitude of the first signal power with the calculated change in the amplitude of the second signal power to derive a degree of coincidence between the first and second signal powers; and
an output section that output to a user the degree of coincidence derived by the processing and calculation section as associated with the particular position of the sensor.

2. The device according to claim 1, wherein the sensor is moved to a plurality of positions in the vicinity of the subject electronic device,
wherein the processing and calculation section receives the first digital values and the second digital values obtained for the prescribed period of time for each of the plurality of positions assumed by the sensor; the processing and calculation section calculates the change in the amplitude of the first signal power and the change in the amplitude of the second signal power over the prescribed period of time, respectively, for each of the plurality of positions of the sensor; and the processing and calculation section further compares the calculated change in the amplitude of the first signal power with the calculated change in the amplitude of the second signal power to derive the degree of coincidence between the first and second signal powers for each of the plurality of positions of the sensor, and
wherein the output section outputs the degrees of coincidence with the associated positions of the sensor as depicted in term of positions on the subject electronic device in a form of map.

3. The device according to claim 1, wherein the processing and calculation section calculates an amplitude change of the first signal power and an amplitude change of the second signal power during each of prescribed time intervals that constitute said prescribed period of time, and calculates an absolute value of a difference between said two amplitude changes for each of the prescribed time intervals, and the processing and calculation section derives the degree of coincidence based on said calculated absolute value of the difference between said two amplitude changes.

4. The device according to claim 2, wherein the processing and calculation section calculates an amplitude change of the first signal power and an amplitude change of the second signal power during each of prescribed time intervals that constitute said prescribed period of time, and calculates an absolute value of a difference between said two amplitude changes for each of the prescribed time intervals, and the processing and calculation section derives the degree of coincidence based on said calculated absolute value of the difference between said two amplitude changes.

5. The device according to claim 1, wherein the second signal power is signal power outputted from an antenna provided in the electronic device under interference.

6. The device according to claim 1, wherein the second signal power is signal power outputted from an EMI measurement antenna.

7. A device for identifying a location of electromagnetic interference source, comprising:
a sensor disposed to be movable in a vicinity of a subject electronic device that is suspected to emit interfering electromagnetic wave, the sensor receiving near-field electromagnetic field emitted from the subject electronic device, and outputting a signal power of said received near-field electromagnetic field as a first signal power;
a first signal detection section that receives the first signal power outputted from the sensor, the first signal detection section outputting a first phase digital value that corresponds to a phase of said first signal power determined relative to a prescribed reference signal;
a second signal detection section that receives a signal power of interference electromagnetic wave received by an electronic device under interference as a second signal power, the second signal detection section outputting a second phase digital value that corresponds to a phase of said second signal power determined relative to said prescribed reference signal;
a processing and calculation section that receives the first phase digital values and the second phase digital values obtained for a prescribed period of time for a particular position of the sensor, the processing and calculation section calculating a stability of a difference between the first phase digital value and the second phase digital value over the prescribed period of time to derive a degree of coincidence between the first and second signal powers for the particular position of the sensor; and
an output section that output to a user the degree of coincidence calculated by the processing and calculation section as associated with the particular position of the sensor.

8. The device according to claim 7, wherein the sensor is moved to a plurality of positions in the vicinity of the subject electronic device,
wherein the processing and calculation section receives the first phase digital values and the second phase digital values obtained for the prescribed period of time for each of the plurality of positions assumed by the sensor; and the processing and calculation section calculates the stability of the difference between the first phase digital value and the second phase digital value over the prescribed period of time to derive the degree of coincidence between the first and second signal powers for each of the plurality of positions of the sensor, and
wherein the output section outputs the degrees of coincidence with the associated positions of the sensor as depicted in term of positions on the subject electronic device in a form of map.

9. The device according to claim 7, wherein the processing and calculation section calculates a phase difference between the first and second phase digital values for each of prescribed sampling times during said prescribed period of time, and derives the degree of coincidence based on said calculated phase differences at the respective sampling times.

10. The device according to claim 8, wherein the processing and calculation section calculates a phase difference between the first and second phase digital values for each of prescribed sampling times during said prescribed period of time, and derives the degree of coincidence based on said calculated phase differences at the respective sampling times.

11. The device according to claim 10, wherein the processing and calculation section calculates temporal statistical values of the phase difference and determines the degree of coincidence based on said temporal statistical values.

12. The device according to claim 7, wherein the second signal power is signal power outputted from an antenna provided in the electronic device under interference.

13. The electromagnetic interference source identification device according to claim 7, wherein the second signal power is signal power outputted from an EMI measurement antenna.

14. A method for identifying a position of a source of interference electromagnetic wave, comprising:
(a) moving a sensor to a particular position in a vicinity of a subject electronic device that is suspected to emit interference electromagnetic wave, the sensor receiving near-field electromagnetic field and outputting a signal power of said received near-field electromagnetic field as a first signal power;
(b) processing said first signal power to generate a first digital value that corresponds to an amplitude of said first signal power;
(c) receiving and processing a signal power of interference electromagnetic wave received by an electronic device under interference as second signal power to generate a second digital value that corresponds to an amplitude of said second signal power;
(d) receiving the generated first digital value at prescribed sampling intervals for a duration of a prescribed period of time, and storing the received first digital values in a first memory as associated with said particular position of the sensor;
(e) receiving the generated second digital value at said prescribed sampling intervals for the duration of said prescribed period of time, and storing the received second digital values in a second memory as associated with said particular position of the sensor;
(f) comparing a change in the first digital value stored with a change in the second digital value in each of said sampling intervals to derive a degree of coincidence between said the first and second signal powers; and
(g) outputting to a user the derived degree of coincidence as associated with the particular position of the sensor.

15. The method according to claim 14, further comprising moving the sensor to a plurality of positions in the vicinity of the subject electronic device,
wherein the steps (a) through (f) are performed for each of the plurality of positions of the sensor to derive the degree of coincidence for each of the plurality of the sensor positions, and
wherein the step (e) includes outputting the degrees of coincidence with the associated positions of the sensor as depicted in term of positions on the subject electronic device in a form of map.

16. The method according to claim 14, wherein the step (f) includes calculating an amplitude change of the first signal power and an amplitude change of the second signal power during each of prescribed time intervals that constitute said prescribed period of time, and calculating an absolute value of a difference between said two amplitude changes for each of the prescribed time intervals, and deriving the degree of coincidence based on said calculated absolute value of the difference between said two amplitude changes.

17. The method according to claim 15, wherein the step (f) includes calculating an amplitude change of the first signal power and an amplitude change of the second signal power during each of prescribed time intervals that constitute said prescribed period of time, and calculating an absolute value of a difference between said two amplitude changes for each of the prescribed time intervals, and deriving the degree of coincidence based on said calculated absolute value of the difference between said two amplitude changes.

18. A method for identifying a position of a source of interference electromagnetic wave, comprising:
(a) moving a sensor to a particular position in a vicinity of a subject electronic device that is suspected to emit interference electromagnetic wave, the sensor receiving near-field electromagnetic field and outputting a signal power of said received near-field electromagnetic field as a first signal power;
(b) processing said first signal power to generate a first phase digital value that corresponds to a phase of said first signal power determined relative to a prescribed reference signal;
(c) receiving and processing a signal power of interference electromagnetic wave received by an electronic device under interference as a second signal power to generate a second phase digital value that corresponds to a phase of said second signal power determined relative to said prescribed reference signal;
(d) receiving the generated first phase digital value at prescribed sampling intervals for a duration of a prescribed period of time, and storing the received first phase digital values in a first memory as associated with said particular position of the sensor;
(e) receiving the generated second phase digital value at said prescribed sampling intervals for the duration of said prescribed period of time, and storing the received second phase digital values in a second memory as associated with said particular position of the sensor;
(f) deriving a degree of coincidence between said the first and second signal powers for that particular position of the sensor in accordance with a stability of a difference between the first phase digital value and the second phase digital value over the prescribed period of time; and
(g) outputting to a user the derived degree of coincidence as associated with the particular position of the sensor.

19. The method according to claim 18, further comprising moving the sensor to a plurality of positions in the vicinity of the subject electronic device,
wherein the steps (a) through (f) are performed for each of the plurality of positions of the sensor to derive the degree of coincidence for each of the plurality of the sensor positions, and
wherein the step (e) includes outputting the degrees of coincidence with the associated positions of the sensor as depicted in term of positions on the subject electronic device in a form of map.

20. The method according to claim 18, wherein the step (f) includes calculating a phase difference between the first and second phase digital values for each of prescribed sampling times during said prescribed period of time, and deriving the degree of coincidence based on said calculated phase differences at the respective sampling times.

21. The method according to claim 19, wherein the step (f) includes calculating a phase difference between the first and second phase digital values for each of prescribed sampling times during said prescribed period of time, and deriving the degree of coincidence based on said calculated phase differences at the respective sampling times.

22. A computer readable information recording medium having a computer program stored thereon, the computer program being for installation in a computer device that functions as the processing and calculation section of the device set forth in claim 1 and instructing the computer device to operate as the processing and calculation section set forth in claim 1.

23. A computer readable information recording medium having a computer program stored thereon, the computer program being for installation in a computer device that functions as the processing and calculation section of the device set forth in claim 2 and instructing the computer device to operate as the processing and calculation section set forth in claim 2.

24. A computer readable information recording medium having a computer program stored thereon, the computer program being for installation in a computer device that functions as the processing and calculation section of the device set forth in claim 3 and instructing the computer device to operate as the processing and calculation section set forth in claim 3.

25. A computer readable information recording medium having a computer program stored thereon, the computer program being for installation in a computer device that functions as the processing and calculation section of the device set forth in claim 4 and instructing the computer device to operate as the processing and calculation section set forth in claim 4.

26. A computer readable information recording medium having a computer program stored thereon, the computer program being for installation in a computer device that functions as the processing and calculation section of the device set forth in claim 7 and instructing the computer device to operate as the processing and calculation section set forth in claim 7.

27. A computer readable information recording medium having a computer program stored thereon, the computer program being for installation in a computer device that functions as the processing and calculation section of the device set forth in claim 8 and instructing the computer device to operate as the processing and calculation section set forth in claim 8.

28. A computer readable information recording medium having a computer program stored thereon, the computer program being for installation in a computer device that functions as the processing and calculation section of the device set forth in claim 9 and instructing the computer device to operate as the processing and calculation section set forth in claim 9.

29. A computer readable information recording medium having a computer program stored thereon, the computer program being for installation in a computer device that functions as the processing and calculation section of the device set forth in claim 10 and instructing the computer device to operate as the processing and calculation section set forth in claim 10.

30. The device according to claim 1, wherein said first signal detection section further outputs a first phase digital value that corresponds to a phase of said first signal power determined relative to a prescribed reference signal,
wherein said second signal detection section further outputs a second phase digital value that corresponds to a phase of said second signal power determined relative to said prescribed reference signal,
wherein said processing and calculation section further receives the first phase digital values and the second phase digital values obtained for the prescribed period of time for the particular position of the sensor, and said processing and calculation section calculates a stability of a phase difference between the first phase digital value and the second phase digital value over the prescribed period of time and derives a combined degree of coincidence for the particular position of the sensor in accordance with said stability of the phase difference and the said degree of coincidence derived based on the amplitudes, and
wherein an output section outputs to a user the combined degree of coincidence calculated by the processing and calculation section as associated with the particular position of the sensor.
